(19) United States
(12) Patent Application Publication
(10) Pub. No.: US 2026/0282681 A1
(43) Pub. Date: Sep. 17, 2026

(54) DISPLAY DEVICE AND ELECTRONIC DEVICE INCLUDING THE SAME

(71) Applicant: Samsung Display Co., LTD., Yongin-si (KR)

(72) Inventors: Jong Hyun CHOI, Yongin-si (KR); Young Woon KHO, Yongin-si (KR)

(21) Appl. No.: 19/536,525

(22) Filed: Feb. 11, 2026

(30) Foreign Application Priority Data
Mar. 14, 2025 (KR) 10-2025-0033197

(51) Int. Cl. H10K 59/131; H10K 59/80

(52) U.S. Cl. CPC H10K 59/131; H10K 59/8731

(57) ABSTRACT

A display device includes a first substrate and a second substrate facing each other; and a filling layer filled between the first substrate and the second substrate. Each of the first substrate and the second substrate includes a display area in which emission areas are arranged; a non-display area located around the display area; a light transmitting area surrounded by the display area; and a light transmitting peripheral area located between the light transmitting area and the display area in a plan view. The first substrate includes two or more bonding auxiliary layers located in the light transmitting peripheral area, having a ring shape surrounding the light transmitting area, and spaced apart from each other in the plan view. The first substrate defines therein a light transmitting hole overlapping the light transmitting area. The filling layer is in contact with the support substrate through the light transmitting hole.

This application claims priority to Korean Patent Application No. 10-2025-0033197, filed on Mar. 14, 2025, and all the benefits accruing therefrom under 35 U.S.C. §119, the content of which in its entirety is herein incorporated by reference.

### BACKGROUND

### 1. Technical Field

The present disclosure relates to a display device and an electronic device including the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer containing an organic light emitting material. As described above, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area in which an image is displayed, and a non-display area around the display area. Emission areas for emitting light with respective luminances and colors may be arranged in the display area.

### SUMMARY

The display device may include a first substrate and a second substrate that face each other and are bonded together to improve strength, and a filling layer filled between the first substrate and the second substrate.

An optical device located below the display device may perform a sensing operation for detecting light transmitted through the display device.

However, due to interfaces between the first substrate, the filling layer, and the second substrate overlapping a light transmission area, the amount of light (hereinafter also referred to as "light transmittance") transmitted to the optical device through the display device may be low, thereby making it difficult to improve the sensing reliability of the optical device.

In view of the foregoing, aspects of the present disclosure provide a display device that includes a first substrate and a second substrate bonded together to improve strength, and that allows light transmittance to be improved, and an electronic device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device includes a first substrate and a second substrate facing each other and bonded together; and a filling layer filled between the first substrate and the second substrate. Each of the first substrate and the second substrate includes a display area in which emission areas are arranged; a non-display area located around the display area in a plan view; a light transmitting area surrounded by the display area in the plan view; and a light transmitting peripheral area located between the light transmitting area and the display area in the plan view. The first substrate includes a support substrate; two or more bonding auxiliary layers located in the light transmitting peripheral area, having a ring shape surrounding the light transmitting area, and spaced apart from each other in the plan view; a circuit layer located on the support substrate; an element layer located on the circuit layer; and an encapsulation layer covering the element layer. The first substrate defines therein a light transmitting hole overlapping the light transmitting area. The encapsulation layer includes a first encapsulation layer located on the element layer and the two or more bonding auxiliary layers and containing an inorganic insulating material; a second encapsulation layer located on the first encapsulation layer and containing an organic insulating material; and a third encapsulation layer covering the second encapsulation layer and containing an inorganic insulating material. The light transmitting hole is defined in the first encapsulation layer and the third encapsulation layer. The filling layer is in contact with the support substrate through the light transmitting hole.

The first substrate may further include at least one light transmitting peripheral dam located between the two or more bonding auxiliary layers. The second encapsulation layer may be spaced apart from the light transmitting area by the at least one light transmitting peripheral dam. In a portion of the light transmitting peripheral area between the at least one light transmitting peripheral dam and the light transmitting area, the third encapsulation layer may be in contact with the first encapsulation layer.

The element layer may include first electrodes located in the emission areas; a pixel defining layer located in a non-emission area between the emission areas of the display area and covering edges of the first electrodes; first common layers located on the first electrodes; light emitting layers located on the first common layers; a second common layer located on the pixel defining layer and the light emitting layers; and a second electrode located on the second common layer. The second common layer and the second electrode may overlap the display area, the light transmitting peripheral area, and the light transmitting area. The first encapsulation layer may be in contact with the two or more bonding auxiliary layers through holes which overlap the two or more bonding auxiliary layers in the plan view, respectively, and are defined in the second common layer and the second electrode.

The two or more bonding auxiliary layers may be located on the support substrate. The light transmitting hole may be further defined in one bonding auxiliary layer, which is closest to the light transmitting area among the two or more bonding auxiliary layers.

The display device may further include a light blocking bank located between the first substrate and the second substrate, surrounding the light transmitting area, and overlapping the at least one light transmitting peripheral dam in the plan view. The light blocking bank may contain at least one of a light blocking material that blocks light, a light absorbing material that absorbs light, or a transparent material that has a higher refractive index than the filling layer.

The display device may further include spacers located between the first substrate and the second substrate, overlapping the non-emission area and the light transmitting peripheral area, and spaced apart from each other. Some of the spacers may be located between the light blocking bank and the second substrate.

The first substrate may further include a bank barrier located between the at least one light transmitting peripheral dam and the light transmitting area and surrounding the light transmitting area in the plan view.

The circuit layer may include a plurality of inorganic layers stacked on the support substrate and each containing an inorganic insulating material; and at least one organic layer located on the plurality of inorganic layers and containing an organic insulating material. The at least one light transmitting peripheral dam may be located on the support substrate and spaced apart from the plurality of inorganic layers and the at least one organic layer in the plan view. The bank barrier may be located on the plurality of inorganic layers.

The at least one light transmitting peripheral dam may include a plurality of light transmitting peripheral dam, and the first substrate further may define therein at least one separation groove, which is located in a portion of the light transmitting peripheral area between the plurality of light transmitting peripheral dams, surround the light transmitting area in the plan view, and be defined in the third encapsulation layer and the first encapsulation layer.

The element layer may include first electrodes located in the emission areas; a pixel defining layer located in a non-emission area between the emission areas of the display area and covering edges of the first electrodes; first common layers located on the first electrodes; light emitting layers located on the first common layers; a second common layer located on the pixel defining layer and the light emitting layers; and a second electrode located on the second common layer. The second common layer and the second electrode may overlap the display area, the light transmitting peripheral area, and the light transmitting area. Each of the two or more bonding auxiliary layers may have an undercut structure formed by a main layer and a roof layer located on the main layer and protruding beyond the main layer. The first encapsulation layer may be in contact with a portion of a side surface of the main layer adjacent to the roof layer in each of the two or more bonding auxiliary layers.

The circuit layer may include a plurality of inorganic layers located on the support substrate, each containing an inorganic insulating material, and sequentially stacked; and at least one organic layer located on the plurality of inorganic layers and containing an organic insulating material. The two or more bonding auxiliary layers and the at least one light transmitting peripheral dam may be spaced apart from the at least one organic layer and are arranged on the plurality of inorganic layers. The light transmitting hole may include a first hole defined in the plurality of inorganic layers; and a second hole defined in the second common layer, the second electrode, the first encapsulation layer, and the third encapsulation layer.

The second hole may have a greater width than the first hole. At a periphery of the light transmitting hole, the second common layer, the second electrode, the first encapsulation layer, and the third encapsulation layer may be located on the plurality of inorganic layers.

The display device may further include a light blocking bank located between the first substrate and the second substrate, surrounding the light transmitting area, and overlapping the at least one light transmitting peripheral dam in the plan view. The light blocking bank may contain at least one of a light blocking material that blocks light, a light absorbing material that absorbs light, or a transparent material that has a higher refractive index than the filling layer, and cover an edge of the light transmitting hole.

According to an aspect of the present disclosure, there is provided an electronic device includes a display device for displaying an image; a memory for storing an application; a processor for executing the application and transmitting an image data signal and an input control signal to the display device; and a power module for transmitting power to the display device. The display device includes a first substrate and a second substrate facing each other and bonded together; and a filling layer filled between the first substrate and the second substrate. Each of the first substrate and the second substrate includes a display area in which emission areas are arranged; a non-display area located around the display area in a plan view; a light transmitting area surrounded by the display area in the plan view; and a light transmitting peripheral area located between the light transmitting area and the display area in the plan view. The first substrate includes a support substrate; two or more bonding auxiliary layers located in the light transmitting peripheral area, having a ring shape surrounding the light transmitting area, and spaced apart from each other in the plan view; at least one light transmitting peripheral dam located between the two or more bonding auxiliary layers; a circuit layer located on the support substrate; an element layer located on the circuit layer; and an encapsulation layer covering the element layer. The first substrate defines therein a light transmitting hole overlapping the light transmitting area. The encapsulation layer includes a first encapsulation layer located on the element layer and the two or more bonding auxiliary layers and containing an inorganic insulating material; a second encapsulation layer located on the first encapsulation layer and containing an organic insulating material; and a third encapsulation layer covering the second encapsulation layer and containing an inorganic insulating material. The light transmitting hole is defined in the first encapsulation layer and the third encapsulation layer. The filling layer is in contact with the support substrate through the light transmitting hole. The second encapsulation layer is spaced apart from the light transmitting area by the at least one light transmitting peripheral dam. In a portion of the light transmitting peripheral area between the at least one light transmitting peripheral dam and the light transmitting area, the third encapsulation layer is in contact with the first encapsulation layer.

The display device may further include a light blocking bank located between the first substrate and the second substrate, surrounding the light transmitting area, and overlapping the at least one light transmitting peripheral dam in the plan view. The light blocking bank may contain at least one of a light blocking material that blocks light, a light absorbing material that absorbs light, or a transparent material that has a higher refractive index than the filling layer.

The first substrate may further include a bank barrier located between the at least one light transmitting peripheral dam and the light transmitting area and surrounding the light transmitting area in the plan view.

The at least one light transmitting peripheral dam may include a plurality of light transmitting peripheral dam, and display device may further define therein at least one separation groove, which is located in a portion of the light transmitting peripheral area between the plurality of light transmitting peripheral dams, surround the light transmitting area in the plan view, and be defined in the third encapsulation layer and the first encapsulation layer.

The display device may further include a light blocking bank located between the first substrate and the second substrate, surrounding the light transmitting area, and overlapping the at least one light transmitting peripheral dam in the plan view. The light blocking bank may contain at least one of a light blocking material that blocks light, a light absorbing material that absorbs light, or a transparent material that has a higher refractive index than the filling layer. The light blocking bank may cover the at least one separation groove.

The element layer may include first electrodes located in the emission areas; a pixel defining layer located in a non-emission area between the emission areas of the display area and covering edges of the first electrodes; first common layers located on the first electrodes; light emitting layers located on the first common layers; a second common layer located on the pixel defining layer and the light emitting layers; and a second electrode located on the second common layer. The second common layer and the second electrode may overlap the display area, the light transmitting peripheral area, and the light transmitting area. The first encapsulation layer may be in contact with the two or more bonding auxiliary layers through holes which overlap the two or more bonding auxiliary layers in the plan view, respectively, and be defined in the second common layer and the second electrode.

The element layer may include first electrodes located in the emission areas; a pixel defining layer located in a non-emission area between the emission areas of the display area and covering edges of the first electrodes; first common layers located on the first electrodes; light emitting layers located on the first common layers; a second common layer located on the pixel defining layer and the light emitting layers; and a second electrode located on the second common layer. The second common layer and the second electrode may overlap the display area, the light transmitting peripheral area, and the light transmitting area. Each of the two or more bonding auxiliary layers may have an undercut structure formed by a main layer and a roof layer located on the main layer and protruding beyond the main layer. The first encapsulation layer may be in contact with a portion of a side surface of the main layer adjacent to the roof layer in each of the two or more bonding auxiliary layers. The circuit layer may include a plurality of inorganic layers located on the support substrate, each containing an inorganic insulating material, and sequentially stacked; and at least one organic layer located on the plurality of inorganic layers and containing an organic insulating material. The two or more bonding auxiliary layers and the at least one light transmitting peripheral dam may be spaced apart from the at least one organic layer and are located on the plurality of inorganic layers. The light transmitting hole may include a first hole defined in the plurality of inorganic layers; and a second hole defined in the second common layer, the second electrode, the first encapsulation layer, and the third encapsulation layer.

A display device according to one embodiment includes a first substrate and a second substrate that face each other and are bonded together. Accordingly, each of the first substrate and the second substrate has a strength sufficient for a bonding process, so that the strength of the display device may be improved, thereby preventing the display device from being easily damaged.

According to one embodiment, each of the first substrate and the second substrate may include a display area from which light is emitted, a non-display area located around the display area, a light transmitting area surrounded by the display area, and a light transmitting peripheral area located between the display area and the light transmitting area.

The first substrate may include a support substrate, a circuit layer located on the support substrate, an element layer located on the circuit layer, an encapsulation layer covering the element layer, and a light transmitting hole overlapping the light transmitting area.

The encapsulation layer may include a first encapsulation layer including an inorganic insulating material, a second encapsulation layer including an organic insulating material, and a third encapsulation layer including an inorganic insulating material.

The light transmitting hole may be defined in the first encapsulation layer and the third encapsulation layer.

According to one embodiment, the display device may further include a filling layer filled between the first substrate and the second substrate, and the filling layer may be in contact with the support substrate through the light transmitting hole.

In this manner, according to one embodiment, interfaces among the filling layer, the third encapsulation layer, and the first encapsulation layer may be removed by the light transmitting hole, thereby increasing light transmittance through the display device. Accordingly, the sensing reliability of an optical device located below the display device may be improved.

According to one embodiment, since the light transmitting hole is not defined in the support substrate, the filling layer may be in contact with the support substrate through the light transmitting hole. Thus, leakage of the filling layer through the light transmitting hole may be prevented. In addition, even when pressure is applied to bond the first substrate to the second substrate, defects in which cracks in the support substrate are induced or propagated by the light transmitting hole may be prevented.

Therefore, in the display device and the electronic device including the same, light transmittance through the display device may be increased by the light transmitting hole, thereby improving the sensing reliability of the optical device located below the display device, while preventing degradation in strength due to the light transmitting hole.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to one embodiment;

FIG. 2 is an exploded perspective view showing the electronic device of FIG. 1 according to one embodiment;

FIG. 3 is a perspective view illustrating the display device of FIG. 2 according to one embodiment;

FIG. 4 is a plan view illustrating the display device of FIG. 3;

FIG. 5 is a cross-sectional view taken along line A-A' of FIG. 4 according to one embodiment;

FIG. 6 is a schematic diagram showing part B of FIG. 4 according to one embodiment;

FIG. 7 is a block diagram illustrating the display device of FIG. 3 according to one embodiment;

FIG. 8 is an equivalent circuit diagram showing the light emitting pixel driver of FIG. 7 according to one embodiment;

FIG. 9 is a cross-sectional view taken along line D-D' of FIG. 6 according to one embodiment;

FIGS. 10 and 11 are schematic diagrams showing part C of FIG. 4 according to one embodiment;

FIG. 12 is a cross-sectional view taken along line E-E' of FIGS. 10 and 11 according to one embodiment;

FIG. 13 is a flowchart illustrating a method for fabrication of the display device according to one embodiment;

FIGS. 14, 15, 16, 17, and 18 are process diagrams illustrating a step of preparing a first substrate of FIG. 13 according to one embodiment of FIG. 12;

FIGS. 19, 20, 21, 22, 23, 24, 25, 26, and 27 are cross-sectional views taken along line E-E' of FIGS. 10 and 11 according to other embodiments;

FIG. 28 is a block diagram of an electronic device according to one embodiment; and

FIG. 29 is schematic views of electronic devices according to various embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being "on" another layer or substrate, it can be directly on the other layer or substrate, or intervening layers may also be present. In contrast, when an element is referred to as being "directly on" another element, there may be no intervening elements present.

Further, the phrase "in a plan view" means when an object portion is viewed from above (in other words, a view in a thickness direction (i.e., third direction DR3) of the electronic device 10), and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

It will be understood that, although the terms "first," "second," "third," or the like may be used herein to describe various elements, these elements should not be limited by these terms. These terms are used to distinguish one element from another element or for the convenience of description and explanation thereof. For example, when "a first element" is discussed in the description, it may be termed "a second element" or "a third element," and "a second element" and "a third element" may be termed in a similar manner without departing from the teachings herein.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A or B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

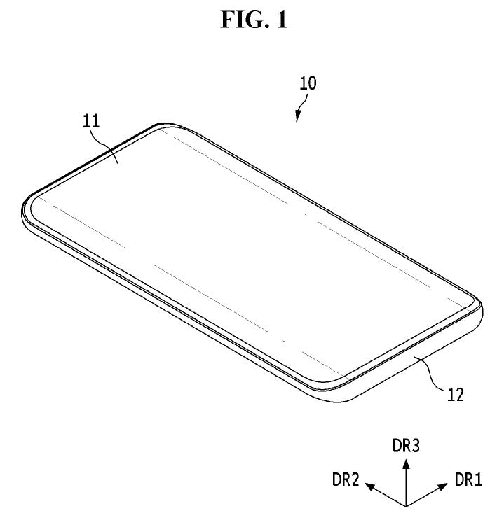

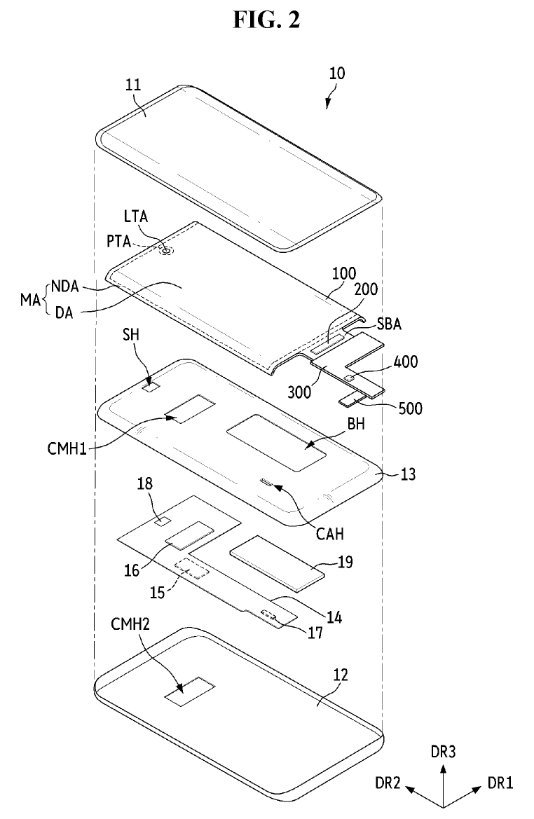

FIG. 1 is a perspective view showing an electronic device according to one embodiment. FIG. 2 is an exploded perspective view showing the electronic device of FIG. 1 according to one embodiment.

Referring to FIG. 1, an electronic device 10 according to one embodiment is a device having a function of displaying an image in a display area. The electronic device 10 may provide portability. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to one embodiment is not limited to a portable electronic device, and may be a large-sized device such as a television, a laptop computer, a monitor, a billboard, and an Internet-of-Things (IoT) device.

The electronic device 10 according to one embodiment may include a cover window 11 and a lower cover 12, which are provided as a housing to protect a display device 100 (see FIG. 2).

Referring to FIG. 2, the electronic device 10 may further include the display device 100, a bracket 13, and a main circuit board 14, which are accommodated between the cover window 11 and the lower cover 12.

The display device 100 may include a display area DA from which light for image display is emitted, a non-display area NDA located around the display area DA, a light transmitting area LTA surrounded by the display area DA, and a light transmitting peripheral area PTA located between the display area DA and the light transmitting area LTA.

A region including the display area DA, the light transmitting area LTA, the light transmitting peripheral area PTA, and the non-display area NDA may be referred to as a main region MA.

The shape of the main region MA in a plan view may correspond to the shape of the electronic device 10 in a plan view.

The display area DA may be located in most of the main region MA. The display area DA may be located at the center of the main region MA.

The display device 100 may further include a sub-region SBA protruding from at least a portion of one edge of the main region MA.

The display device 100 may further include a display driving circuit 200 located in the sub-region SBA, a display circuit board 300 connected and bonded to pads located on one side of the sub-region SBA, a touch driving circuit 400 mounted on the display circuit board 300, and a cable 500 extending from one side of the display circuit board 300.

In the present specification, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 may have a shape close to a rectangular shape in a plan view. For example, the electronic device 10 may have a rectangular shape, in a plan view, having a short side in the first direction DR1 and a long side in the second direction DR2. A corner where the short side in the first direction DR1 and the long side in the second direction DR2 meet may be right-angled or rounded with a selected curvature. The shape of the electronic device 10 in a plan view is not limited to a rectangular shape, and may be one of a polygonal shape, a circular shape, and an elliptical shape, or a shape formed by a combination of two or more thereof.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

That is, the cover window 11 may be located on the display device 100.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

In other words, each of the top, left, and right surface portions of the display device 100 may include the display area DA and the non-display area NDA.

The display area DA may be located on most of each of the top, left, and right surface portions of the display device 100.

The non-display area NDA may be located outside the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from at least a part of one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto.

Since a part of the sub-region SBA is transformed to be bent, another part of the sub-region SBA may overlap the main region MA in the third direction DR3.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

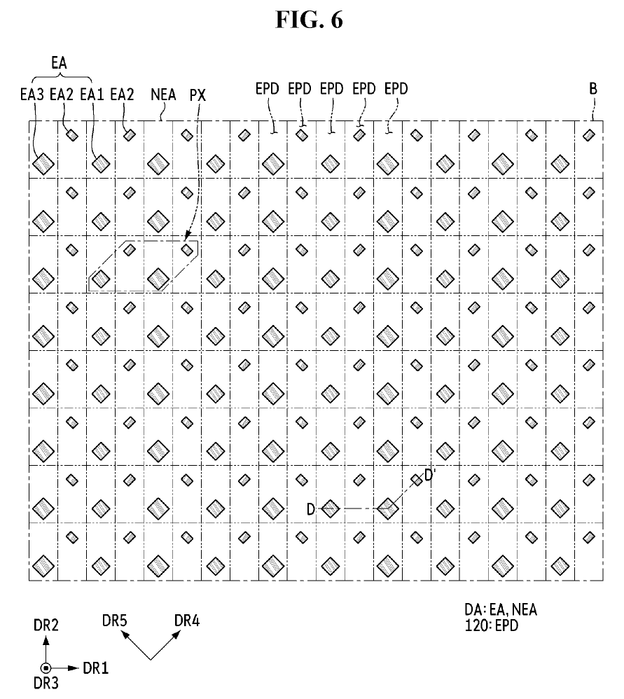

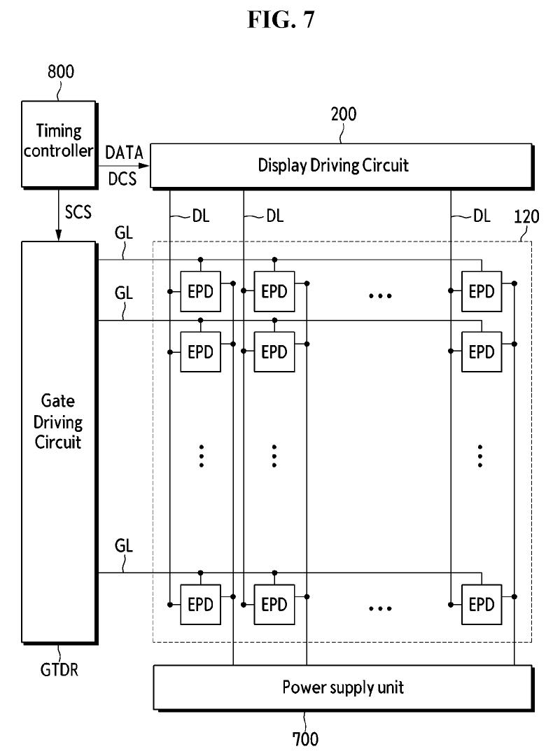

Based on control signals, power and voltages supplied through the display circuit board 300, the display driving circuit 200 may transmit data signals Vdata (see FIG. 7) of light emitting pixel drivers EPD (see FIG. 6) of the display area DA to data lines DL (see FIG. 7).

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and one embodiment is not limited thereto. For example, the display driving circuit 200 may be mounted on the display circuit board 300.

According to one embodiment, the touch driving circuit 400 may be further mounted on the sub-region SBA of the display device 100.

Alternatively, as shown in FIG. 2, the touch driving circuit 400 may be mounted on the display circuit board 300.

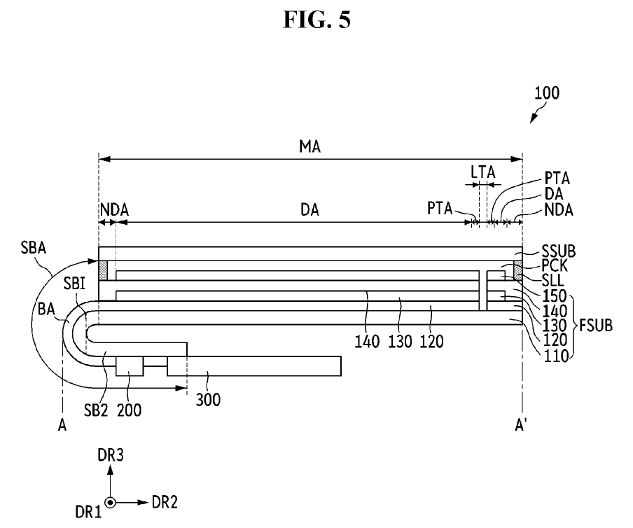

The touch driving circuit 400 may be electrically connected to a touch sensor layer 150 (see FIG. 5) of the display device 100.

As shown in FIG. 2, the bracket 13 may be located under the display device 100.

The bracket 13 may include plastic or metal. The bracket 13 may define therein a first camera hole CMH1 into which a camera device 16 is inserted, a battery hole BH in which a battery 19 is located, an optical device hole SH into which an optical device 18 is inserted, and a cable hole CAH through which the cable 500 connected to the display circuit board 300 passes.

The main circuit board 14 and the battery 19 may be located under the bracket 13.

The main circuit board 14 may be a printed circuit board or a flexible printed circuit board.

A main processor 15, the camera device 16, a main connector 17, and the optical device 18 may be mounted on the main circuit board 14.

The camera device 16 may be located on both the top surface and the bottom surface of the main circuit board 14.

The main processor 15 may be located on the top surface of the main circuit board 14.

The main connector 17 may be located on the bottom surface of the main circuit board 14.

The main processor 15 may be formed as an integrated circuit and control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or approached, and then perform an operation corresponding to the user's touch input or approach input. For example, the main processor 15 may perform an operation or execute an application indicated by an icon touched by the user.

The main processor 15 may be an application processor including an integrated circuit, a central processing unit, or a system chip.

The camera device 16 may process an image frame of a still image or video obtained by an image sensor in a camera mode and output it to the main processor 15.

The cable 500 may pass through the cable hole CAH of the bracket 13 to be connected to the main connector 17. Thus, the main circuit board 14 may be electrically connected to the display circuit board 300.

The optical device 18 may include at least one of a proximity sensor, an illuminance sensor, an iris sensor, or an additional camera sensor.

The proximity sensor, the illumination sensor, the iris sensor, and the second camera sensor may be located on the top surface of the main circuit board 14 and in the optical device hole SH of the bracket 13.

The proximity sensor is a sensor for detecting an object approaching the front surface of the electronic device 10. The proximity sensor may include a light source that outputs light and a light receiver that receives light reflected by an object. The proximity sensor may generate a sensing signal corresponding to the amount of light reflected by the object, and presence or absence of an object near the front surface of the electronic device 10 may be determined based on the sensing signal of the proximity sensor.

The illuminance sensor is a sensor for detecting the brightness of the front surface of the electronic device 10. The illuminance sensor may include a resistor whose resistance value changes according to the brightness of the incident light.

The iris sensor is a sensor for imaging the user's iris. It can be verified whether the user is a pre-registered user based on whether the image captured by the iris sensor is the same as an iris image previously stored in a memory.

The additional camera sensor may process an image frame of a still image or video obtained by the image sensor and output it to the main processor 15. The additional camera sensor may be a complementary metal–oxide–semiconductor (CMOS) image sensor or a charge-coupled device (CCD) sensor. The number of pixels of the additional camera sensor may be smaller than the number of pixels of the camera device 16, and the size of the additional camera sensor may be smaller than the size of the camera device 16.

The battery 19 may be located so as not to overlap the main circuit board 14 in the third direction DR3. The battery 19 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 19. The lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may define therein a second camera hole CMH2 through which the bottom surface of the camera device 16 is exposed.

The position of the camera device 16 in the main region MA, the position of the first camera hole CMH1 in the bracket 13 corresponding to the camera device 16, and the position of the second camera hole CMH2 in the lower cover 12 corresponding to the camera device 16 are not limited by the illustration of FIG. 2.

In addition, the position of the optical device 18 in the main region MA and the position of the optical device hole SH in the bracket 13 are not limited by the illustration of FIG. 2.

Next, the display device 100 according to embodiments will be described.

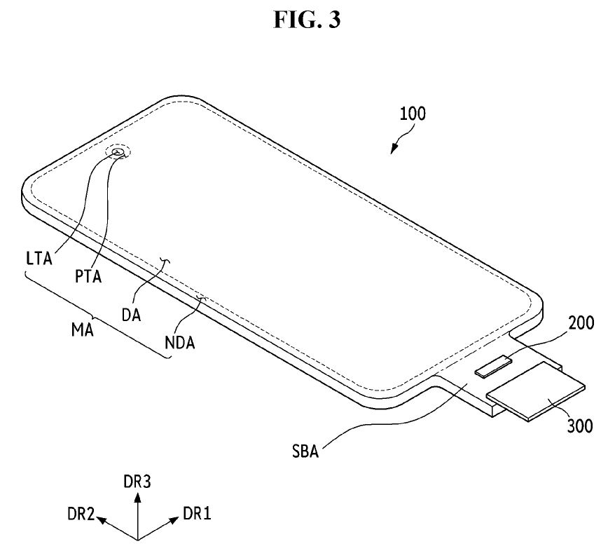

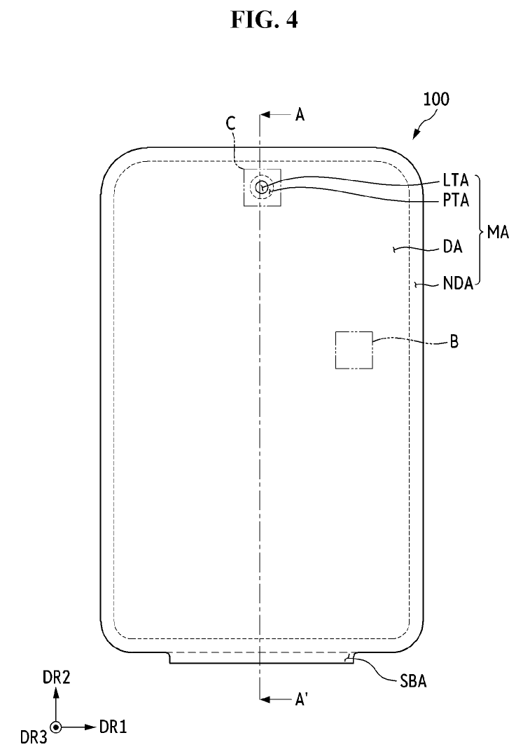

FIG. 3 is a perspective view illustrating the display device of FIG. 2 according to one embodiment. FIG. 4 is a plan view illustrating the display device of FIG. 3. FIG. 5 is a cross-sectional view taken along line A-A' of FIG. 4 according to one embodiment.

Referring to FIGS. 3 and 4, the display device 100 according to one embodiment, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 3, at least one surface of the display device 100 may be a display surface that emits light for displaying an image.

The display surface of the display device 100 may include the main region MA.

The main region MA may include the display area DA from which light for image display is emitted, the non-display area NDA located around the display area DA, the light transmitting area LTA surrounded by the display area DA, and the light transmitting peripheral area PTA located between the display area DA and the light transmitting area LTA.

The main region MA may, in a plan view, be formed in a rectangular shape having short sides in the first direction DR1 and long sides in the second direction DR2 crossing the first direction DR1. The corner where the short side in the first direction DR1 and the long side in the second direction DR2 meet may be rounded to have a selected curvature or may be right-angled. The planar shape of the main region MA is not limited to the rectangular shape, and may be formed in another polygonal shape, a circular shape or an elliptical shape.

The display area DA may be located in most of the main region MA. The display area DA may be located at the center of the main region MA. The display area DA may have a shape similar to a shape of the main region MA.

The display device 100 may further include the sub-region SBA protruding in the second direction DR2 from at least a part of one side of the main region MA.

As shown in FIGS. 4 and 5, a part of the sub-region SBA is transformed to be curved, so that another part of the sub-region SBA may be located on the rear surface of the display device 100.

As shown in FIG. 5, the display device 100 according to one embodiment may include a first substrate FSUB and a second substrate SSUB that face each other and are bonded together, and a filling layer PCK filled between the first substrate FSUB and the second substrate SSUB.

The display device 100 may further include a sealing layer SLL located in the non-display area NDA between the first substrate FSUB and the second substrate SSUB.

The first substrate FSUB and the second substrate SSUB may be bonded together by the sealing layer SLL.

The filling layer PCK may fill a space surrounded by the first substrate FSUB, the second substrate SSUB, and the sealing layer SLL, and may include a transparent organic material.

Each of the first substrate FSUB and the second substrate SSUB may include the main region MA. The main region MA may include the display area DA, the non-display area NDA, the light transmitting area LTA, and the light transmitting peripheral area PTA.

That is, each of the first substrate FSUB and the second substrate SSUB may include the display area DA, the non-display area NDA, the light transmitting area LTA, and the light transmitting peripheral area PTA.

The first substrate FSUB may include a support substrate 110, a circuit layer 120 located on the support substrate 110, an element layer 130 located on the circuit layer 120, and an encapsulation layer 140 covering the element layer 130.

The first substrate FSUB may further include the touch sensor layer 150 located on the encapsulation layer 140.

At least one of the first substrate FSUB or the second substrate SSUB may include a polarizing layer for reducing reflection of external light.

Each of the support substrate 110 and the second substrate SSUB may include at least one material selected from the group consisting of glass, a polymer material, and plastic.

The second substrate SSUB may contain a transparent material.

Each of the support substrate 110 and the second substrate SSUB may have a strength sufficient to maintain its shape without being damaged under the pressure of a bonding process.

The circuit layer 120 may include at least one semiconductor layer, two or more conductive layers, and insulating layers respectively covering them. The circuit layer 120 may include the light emitting pixel drivers EPD (see FIG. 6) corresponding to emission areas EA (see FIG. 6), and each of the light emitting pixel drivers EPD may include two or more transistors electrically connected to wires for transmitting signals or voltages.

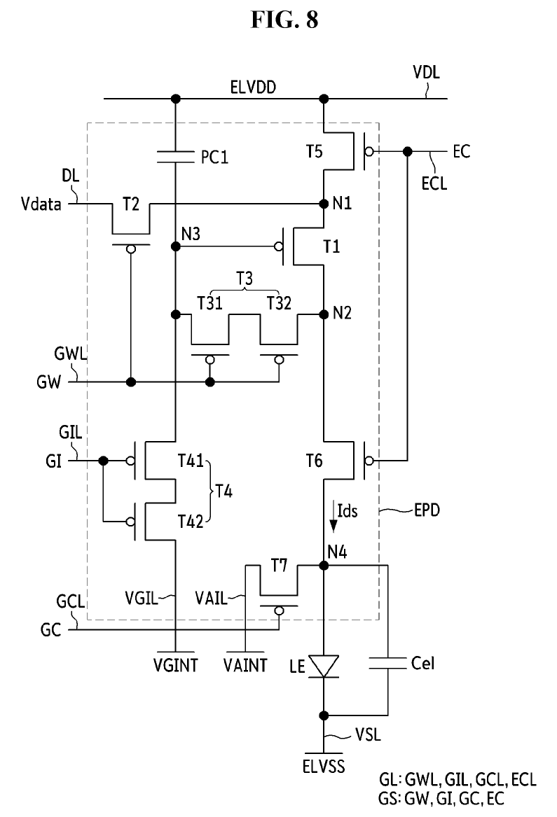

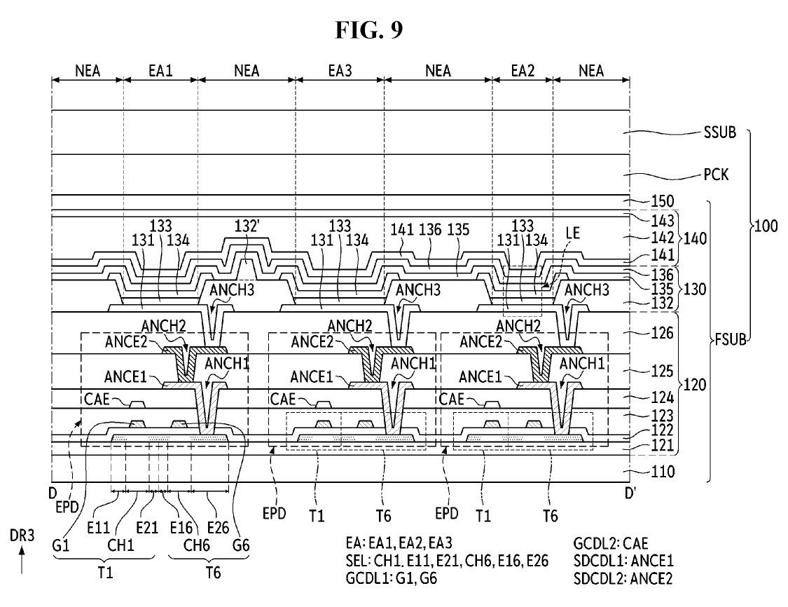

The element layer 130 may include the light emitting elements LE (see FIGS. 8 and 9) located in the emission areas EA.

The encapsulation layer 140 may cover the element layer 130.

The encapsulation layer 140 may have a structure including two or more inorganic insulating layers and at least one organic layer interposed between the inorganic insulating layers.

Since an organic light emitting material of the light emitting elements LE of the element layer 130 may be sealed by the encapsulation layer 140, degradation of the light emitting elements LE due to oxygen or moisture may be delayed or prevented.

The sub-region SBA may include a bending area BA that is transformed into a bent shape, a first sub-region SB1 located between one side of the main region MA and the bending area BA, and a second sub-region SB2 connected to the other side of the bending area BA and overlapping the main region MA in the third direction DR3.

The display driving circuit 200 may be mounted in the second sub-region SB2.

The display circuit board 300 may be bonded to the pads located in the second sub-region SB2 and may be electrically connected to the pads.

FIG. 6 is a schematic diagram showing part B of FIG. 4 according to one embodiment.

Referring to FIG. 6, the display area DA (see FIG. 3) may include emission areas EA that emit light, and a non-emission area NEA located between the emission areas EA.

The emission areas EA may include first emission areas EA1 for emitting light of a first color in a predetermined wavelength band, second emission areas EA2 for emitting light of a second color in a wavelength band lower than a wavelength band of the first color, and third emission areas EA3 for emitting light of a third color in a wavelength band lower than a wavelength band of the second color.

For example, the first color may be red having a wavelength band of approximately 600 nanometers (nm) to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately located in at least one of the first direction DR1 or the second direction DR2.

The second emission areas EA2 may be arranged side by side with each other in at least one of the first direction DR1 or the second direction DR2.

In addition, the second emission areas EA2 may be adjacent to the first emission areas EA1 and the third emission areas EA3 in diagonal directions DR4 and DR5 crossing the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixel PX may be a basic unit for displaying various colors including white with a predetermined luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

The arrangement of the first emission areas EA1, the second emission areas EA2, and the third emission areas EA3 is not limited by the illustration of FIG. 6.

According to one embodiment, the element layer 130 (see FIG. 5) may include light emitting elements LE (see FIGS. 8 and 9) respectively located in the emission areas EA.

The circuit layer 120 (see FIG. 5) may include the light emitting pixel drivers EPD electrically connected to the light emitting elements LE, respectively.

The light emitting pixel drivers EPD may be arranged in the first direction DR1 and the second direction DR2.

FIG. 7 is a block diagram illustrating the display device of FIG. 3 according to one embodiment.

Referring to FIG. 7, the circuit layer 120 of the display device 100 according to one embodiment may include the light emitting pixel drivers EPD respectively electrically connected to the light emitting elements LE (see FIGS. 8 and 9) of the emission areas EA (see FIG. 6), gate lines GL for transmitting gate signals GS (see FIG. 8) to the light emitting pixel drivers EPD, and the data lines DL for transmitting the data signals Vdata (see FIG. 8) to the light emitting pixel drivers EPD.

Each of the gate signals GS is used to control a turn-on/turn-off operation of at least one of two or more transistors provided in each of the light emitting pixel drivers EPD.

Each of the data signals Vdata is used to control the luminance of each of the light emitting elements LE.

According to one embodiment, the display device 100 may further include a gate driver GTDR that outputs gate signals GS to the gate lines GL, a power supply unit 700 that supplies power and voltages to the light emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driver GTDR.

The display driving circuit 200 may convert the image data DATA into analog data voltages according to the data control signal DCS and output the data signals Vdata to the data lines DL.

The gate driver GTDR may generate gate signals in response to the scan control signal SCS and sequentially output the gate signals to gate lines GL.

The gate signals may have pulses that vary to a first gate level voltage or a second gate level voltage.

The power supply unit 700 may supply various power and voltages necessary for driving the light emitting pixel drivers EPD.

FIG. 8 is an equivalent circuit diagram showing the light emitting pixel driver of FIG. 7 according to one embodiment.

Referring to FIG. 8, the light emitting pixel driver EPD of the circuit layer 120 may be electrically connected to a first power line VDL for transmitting a first power ELVDD and the light emitting element LE of the element layer 130, and the light emitting element LE of the element layer 130 may be electrically connected to a second power line VSL for transmitting a second power ELVSS.

The first power ELVDD may have a higher voltage level than the second power ELVSS.

That is, the first electrode (e.g., anode electrode) of the light emitting element LE may be electrically connected to the light emitting pixel driver EPD, and the second electrode (e.g., cathode electrode) of the light emitting element LE may be electrically connected to the second power line VSL.

A capacitor Cel connected in parallel with the light emitting element LE refers to a parasitic capacitance between the first electrode and the second electrode.

According to one embodiment, the light emitting pixel driver EPD may include a first transistor T1 configured to generate a driving current Ids for driving the light emitting element LE, two or more transistors T2 to T7 electrically connected to the first transistor T1 or the light emitting element LE, and a first capacitor PC1.

The light emitting pixel driver EPD may be electrically connected to the gate lines GL for transmitting the gate signals GS and the data line DL for transmitting the data signal Vdata.

The gate signals GS may include a scan write signal GW for turn-on/turn-off operations of a second transistor T2 and a third transistor T3, a scan initialization signal GI for a turn-on/turn-off operation of a fourth transistor T4, an emission control signal EC for turn-on/turn-off operations of a fifth transistor T5 and a sixth transistor T6, and a gate control signal GC for a turn-on/turn-off operation of a seventh transistor T7.

That is, the gate lines GL may include a scan write line GWL for transmitting the scan write signal GW, a scan initialization line GIL for transmitting the scan initialization signal GI, an emission control line ECL for transmitting the emission control signal EC, and a gate control line GCL for transmitting the gate control signal GC.

The light emitting pixel driver EPD may be electrically connected to a first initialization voltage line VGIL configured to transmit a first initialization voltage VGINT for initializing a potential of the gate electrode of the first transistor T1, and a second initialization voltage line VAIL configured to transmit a second initialization voltage VAINT for initializing a potential of the first electrode of the light emitting element LE.

The first transistor T1 may be electrically connected between a first node N1 and a second node N2.

The first node N1 may be electrically connected to the first electrode (e.g., source electrode) of the first transistor T1.

The second node N2 may be electrically connected to the second electrode (e.g., drain electrode) of the first transistor T1.

The gate electrode of the first transistor T1 may be electrically connected to a third node N3.

The second transistor T2 may be electrically connected between the data line DL and the first node N1.

The gate electrode of the second transistor T2 may be electrically connected to the scan write line GWL, and the second transistor T2 may be turned on by the scan write signal GW.

The first capacitor PC1 may be electrically connected between the third node N3 and the first power line VDL.

The potential of the gate electrode of the first transistor T1 may correspond to a voltage charged in the first capacitor PC1.

When the second transistor T2 is turned on, the data signal Vdata of the data line DL is transmitted to the first electrode of the first transistor T1, so that the voltage difference between the gate electrode of the first transistor T1 and the first electrode of the first transistor T1 may be a difference voltage between a first power source ELVDD and the data signal Vdata.

In this case, when the voltage difference between the gate electrode of the first transistor T1 and the first electrode of the first transistor T1, i.e., the gate-source voltage difference becomes equal to or greater than a threshold voltage, the first transistor T1 is turned on, so that a drain-source current Ids of the first transistor T1 corresponding to the data signal Vdata may be generated.

The fifth transistor T5 may be electrically connected between the first node N1 and the first power line VDL.

The sixth transistor T6 may be electrically connected between the second node N2 and a fourth node N4.

The fourth node N4 may be electrically connected to the first electrode of the light emitting element LE.

The gate electrode of the fifth transistor T5 and the gate electrode of the sixth transistor T6 may be electrically connected to the emission control line ECL, and the fifth transistor T5 and the sixth transistor T6 may be turned on by the emission control signal EC.

When the fifth transistor T5 and the sixth transistor T6 are turned on, the first transistor T1 and the light emitting element LE may be connected in series between the first power source ELVDD and a second power source ELVSS. Accordingly, the drain-source current Ids of the first transistor T1 corresponding to the data signal Vdata may be transmitted as a driving current of the light emitting element LE.

Accordingly, the light emitting element LE may emit light having a luminance corresponding to the data signal Vdata.

The third transistor T3 may be electrically connected between the second node N2 and the third node N3.

That is, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

The first electrode of the first sub-transistor T31 may be connected to the gate electrode of the first transistor T1, the second electrode of the first sub-transistor T31 may be connected to the first electrode of the second sub-transistor T32, and the second electrode of the second sub-transistor T32 may be connected to the second electrode of the first transistor T1.

In this way, it is possible to prevent the potential of the gate electrode of the first transistor T1 from changing due to the leakage current caused by the third transistor T3 that is not turned on.

The gate electrode of the first sub-transistor T31 and the gate electrode of the second sub-transistor T32 may be electrically connected to the scan write line GWL, and the first sub-transistor T31 and the second sub-transistor T32 may be turned on by the scan write signal GW.

When the first sub-transistor T31 and the second sub-transistor T32 are turned on, the voltage difference between the second node N2 and the third node N3 may be initialized.

The fourth transistor T4 may be electrically connected between the third node N3 and the first initialization voltage line VGIL. That is, the fourth transistor T4 may be connected between the gate electrode of the first transistor T1 and the first initialization voltage line VGIL.

The fourth transistor T4 may include a plurality of sub-transistors connected in series. For example, the fourth transistor T4 may include a third sub-transistor T41 and a fourth sub-transistor T42.

The first electrode of the third sub-transistor T41 may be connected to the gate electrode of the first transistor T1, the second electrode of the third sub-transistor T41 may be connected to the first electrode of the fourth sub-transistor T42, and the second electrode of the fourth sub-transistor T42 may be connected to the first initialization voltage line VGIL.

In this way, it is possible to prevent the potential of the gate electrode of the first transistor T1 from changing due to the leakage current caused by the fourth transistor T4 that is not turned on.

The gate electrode of the third sub-transistor T41 and the gate electrode of the fourth sub-transistor T42 may be electrically connected to the scan initialization line GIL, and the third sub-transistor T41 and the fourth sub-transistor T42 may be turned on by the scan initialization signal GI.

When the third sub-transistor T41 and the fourth sub-transistor T42 are turned on, the potential of the third node N3 may be initialized to the first initialization voltage VGINT.

The seventh transistor T7 may be electrically connected between the fourth node N4 and the second initialization voltage line VAIL.

The gate electrode of the seventh transistor T7 may be electrically connected to the gate control line GCL, and the seventh transistor T7 may be turned on by the gate control signal GC.

When the seventh transistor T7 is turned on, the potential of the fourth node N4 and the first electrode of the light emitting element LE electrically connected to the fourth node N4 may be initialized to the second initialization voltage VAINT.

According to one embodiment, the first to seventh transistors T1 to T7 may be formed as P-type MOSFETs.

According to another embodiment, the first to seventh transistors T1 to T7 may be formed as N-type MOSFETs.

According to still another embodiment, some of the first to seventh transistors T1 to T7 may be formed as N-type MOSFETs, and the others thereof may be formed as P-type MOSFETs. In one example, the third transistor T3 and the fourth transistor T4 may be formed as N-type MOSFETs, and the first transistor T1, the second transistor T2, the fifth transistor T5, the sixth transistor T6, and the seventh transistor T7 may be formed as P-type MOSFETs.

FIG. 9 is a cross-sectional view taken along line D-D' of FIG. 6 according to one embodiment.

FIG. 9 illustrates the first transistor T1, the sixth transistor T6, and the light emitting element LE.

Referring to FIG. 9, the display device 100 according to one embodiment may include the first substrate FSUB and the second substrate SSUB facing each other, and the filling layer PCK filled between the first substrate FSUB and the second substrate SSUB.

According to one embodiment, the first substrate FSUB may include the support substrate 110, the circuit layer 120 located on the support substrate 110, the element layer 130 located on the circuit layer 120, and the encapsulation layer 140 covering the element layer 130.

The first substrate FSUB may further include the touch sensor layer 150 located on the encapsulation layer 140.

According to one embodiment, the encapsulation layer 140 may include a first encapsulation layer 141 located on the element layer 130 and containing an inorganic insulating material, a second encapsulation layer 142 located on the first encapsulation layer 141 and containing an organic insulating material, and a third encapsulation layer 143 covering the second encapsulation layer 142 and containing an inorganic insulating material.

The circuit layer 120 may include a plurality of inorganic layers 121, 122, 123 and 124 stacked on the support substrate 110 and each including an inorganic insulating material, and at least one organic layer 125 and 126 located on the plurality of inorganic layers 121, 122, 123 and 124 and including an organic insulating material.

According to one embodiment, the plurality of inorganic layers 121, 122, 123 and 124 may include a buffer layer 121 covering the support substrate 110, a first gate insulating layer 122 covering a semiconductor layer SEL on the buffer layer 121, a second gate insulating layer 123 covering a first gate conductive layer GCDL1 on the first gate insulating layer 122, and an interlayer-insulating layer 124 covering a second gate conductive layer GCDL2 on the second gate insulating layer 123.

In addition, the at least one organic layer 125 and 126 may include a first planarization layer 125 covering a first source/drain conductive layer SDCDL1 on the interlayer-insulating layer 124, and a second planarization layer 126 covering a second source/drain conductive layer SDCDL2 on the first planarization layer 125.

The semiconductor layer SEL may include channel portions CH1 and CH6, first electrode portions E11 and E16, and second electrode portions E21 and E26 of the first and sixth transistors T1 and T6.

In addition, when the second transistor T2, the third transistor T3, the fourth transistor T4, the fifth transistor T5 and the seventh transistor T7 are P-type MOSFETs, as is the case with the first transistor T1 and the sixth transistor T6, the semiconductor layer SEL may further include channel portions, first electrode portions, and second electrode portions of the second transistor T2, the third transistor T3, the fourth transistor T4, the fifth transistor T5 and the seventh transistor T7.

The second electrode portion E21 of the first transistor T1 may be connected to the first electrode portion E16 of the sixth transistor T6.

The first gate conductive layer GCDL1 may include the gate electrodes G1 and G6 of the first transistor T1 and the sixth transistor T6, respectively.

The gate electrode G1 of the first transistor T1 may overlap the channel portion CH1 of the first transistor T1 in the third direction DR3.

The gate electrode G6 of the sixth transistor T6 may overlap the channel portion CH6 of the sixth transistor T6 in the third direction DR3.

The second gate conductive layer GCDL2 may include a capacitor electrode CAE.

The capacitor electrode CAE may overlap the gate electrode G1 of the first transistor T1 in the third direction DR3.

The capacitor electrode CAE may be electrically connected to the first power line VDL (see FIG. 8).

Accordingly, the first capacitor PC1 may be formed by a region in which the capacitor electrode CAE and the gate electrode G1 of the first transistor T1 overlap each other in the third direction DR3.

The first source-drain conductive layer SDCDL1 may include the first anode connection electrode ANCE1.

The first anode connection electrode ANCE1 may be electrically connected to the second electrode portion E26 of the sixth transistor T6 through a first anode connection hole ANCH1.

The second source-drain conductive layer SDCDL2 may include the second anode connection electrode ANCE2.

The second anode connection electrode ANCE2 may be electrically connected to the first anode connection electrode ANCE1 through a second anode connection hole ANCH2.

The element layer 130 may include first electrodes 131 located in the emission areas EA, a pixel defining layer 132 located in the non-emission area NEA and covering edges of the first electrodes 131, first common layers 133 located on the first electrodes 131, light emitting layers 134 located on the first common layers 133, a second common layer 135 located on the pixel defining layer 132 and the light emitting layers 134, and a second electrode 136 located on the second common layer 135.

The element layer 130 may further include auxiliary spacers 132' located on the pixel defining layer 132 and spaced apart from each other.

In this case, the second common layer 135 may be located on the pixel defining layer 132, the auxiliary spacers 132', and the light emitting layers 134.

Each of the light emitting elements LE of the emission areas EA may have a structure in which the first common layer 133, the light emitting layer 134, and the second common layer 135 are interposed between the first electrode 131 and the second electrode 136.

The first electrode 131 may be located on the second planarization layer 126, and may be electrically connected to the second anode connection electrode ANCE2 through a third anode connection hole ANCH3.

Accordingly, the first electrode 131 may be electrically connected to the second electrode portion E26 of the sixth transistor T6 through the first anode connection electrode ANCE1 and the second anode connection electrode ANCE2.

The first electrodes 131 may be respectively located in the emission areas EA and respectively electrically connected to the light emitting pixel drivers EPD, and thus may be referred to as pixel electrodes or anode electrodes.

The second electrode 136 may be located in the entire display area DA including the emission areas EA and the non-emission area NEA and is shared by the light emitting elements LE, and thus may be referred to as a common electrode or a cathode electrode.

Each of the first common layers 133 may include a hole transport layer. Additionally, each of the first common layers 133 may further include a hole injection layer.

The second common layer 135 may include an electron transport layer. Additionally, the second common layer 135 may further include an electron injection layer.

Each of the light emitting layers 134 may include an organic light emitting material.

The pixel defining layer 132 may include an organic insulating material.

The touch sensor layer 150 may be located on the encapsulation layer 140. The touch sensor layer 150 may include touch electrodes for detecting a signal that varies depending on the touch of a person or an object and sensing a point on the display surface where the touch of the person or the object has occurred.

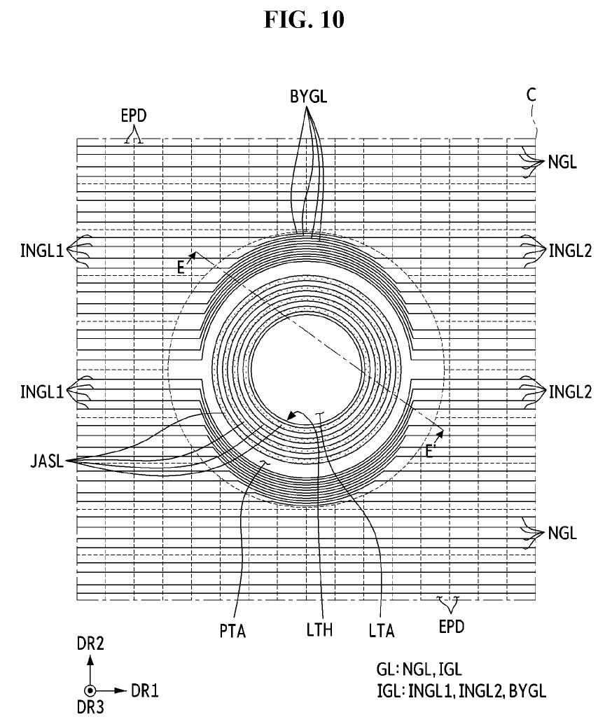

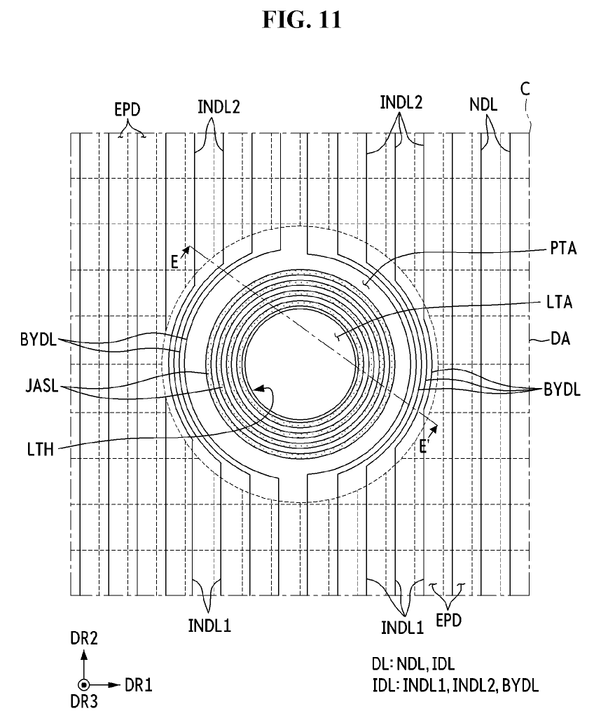

FIGS. 10 and 11 are schematic diagrams showing part C of FIG. 4 according to one embodiment.

FIGS. 10 and 11 illustrate the light transmitting area LTA, the light transmitting peripheral area PTA, and the first substrate FSUB in a portion of the display area DA adjacent to the light transmitting peripheral area PTA.

FIG. 10 illustrates the gate lines GL, and FIG. 11 illustrates the data lines DL.

Referring to FIGS. 10 and 11, the first substrate FSUB of the display device 100 according to one embodiment may include two or more bonding auxiliary layers JASL, which are located in the light transmitting peripheral area PTA, have a ring shape surrounding the light transmitting area LTA, and are spaced apart from each other, and may define therein a light transmitting hole LTH overlapping the light transmitting area LTA.

The light transmitting hole LTH is intended to improve light transmittance of the light transmitting area LTA by reducing interfaces overlapping the light transmitting area LTA.

The two or more bonding auxiliary layers JASL are provided to assist sealing around the light transmitting hole LTH.

The circuit layer 120 may include the light emitting pixel drivers EPD arranged in the display area DA, and the gate lines GL and the data lines DL electrically connected to the light emitting pixel drivers EPD.

According to one embodiment, as the light transmitting hole LTH is defined in the light transmitting area LTA, the wires, including the gate lines GL and the data lines DL, of the circuit layer 120 cannot be located in the light transmitting area LTA.

In other words, each wire of the circuit layer 120 may be classified as either a crossing wire or a general wire depending on whether it crosses the light transmitting area LTA and the light transmitting peripheral area PTA.

The general wire may be spaced apart from the light transmitting area LTA and the light transmitting peripheral area PTA in the first direction DR1 and the second direction DR2, and may extend in one direction.

The crossing wire crosses the light transmitting area LTA and the light transmitting peripheral area PTA. Accordingly, the crossing wire includes two divided lines located on opposite sides of the light transmitting peripheral area PTA and extending in one direction, and a bypass line located in the light transmitting peripheral area PTA and electrically connecting the two divided lines to each other.

In one example, as shown in FIG. 10, the gate lines GL extending in the first direction DR1 may include general gate lines NGL that do not cross the light transmitting area LTA and the light transmitting peripheral area PTA, and crossing gate lines IGL that cross the light transmitting area LTA and the light transmitting peripheral area PTA.

Each of the general gate lines NGL may extend in the first direction DR1.

Each of the crossing gate lines IGL may include a first divided gate line INGL1, which extends in the first direction DR1 and is located on one side (left side in FIG. 10) of the light transmitting peripheral area PTA in the first direction DR1, a second divided gate line INGL2, which extends in the first direction DR1 and is located on the other side (right side in FIG. 10) of the light transmitting peripheral area PTA in the first direction DR1, and a bypass gate line BYGL, which is located in the light transmitting peripheral area PTA, bypasses the light transmitting area LTA, and electrically connects the first divided gate line INGL1 to the second divided gate line INGL2.

The bypass gate line BYGL may have a curved shape extending along the outer boundary of the light transmitting area LTA.

In another example, as shown in FIG. 11, the data lines DL extending in the second direction DR2 may include general data lines NDL that do not cross the light transmitting area LTA and the light transmitting peripheral area PTA, and crossing data lines IDL that cross the light transmitting area LTA and the light transmitting peripheral area PTA.

Each of the general data lines NDL may extend in the second direction DR2.

Each of the crossing data lines IDL may include a first divided data line INDL1, which extends in the second direction DR2 and is located on one side (lower side in FIG. 11) of the light transmitting peripheral area PTA in the second direction DR2, a second divided data line INDL2, which extends in the second direction DR2 and is located on the other side (upper side in FIG. 11) of the light transmitting peripheral area PTA in the second direction DR2, and a bypass data line BYDL, which is located in the light transmitting peripheral area PTA, bypasses the light transmitting area LTA, and electrically connects the first divided data line INDL1 to the second divided data line INDL2.

The bypass data line BYDL may have a curved shape extending along the outer boundary of the light transmitting area LTA.

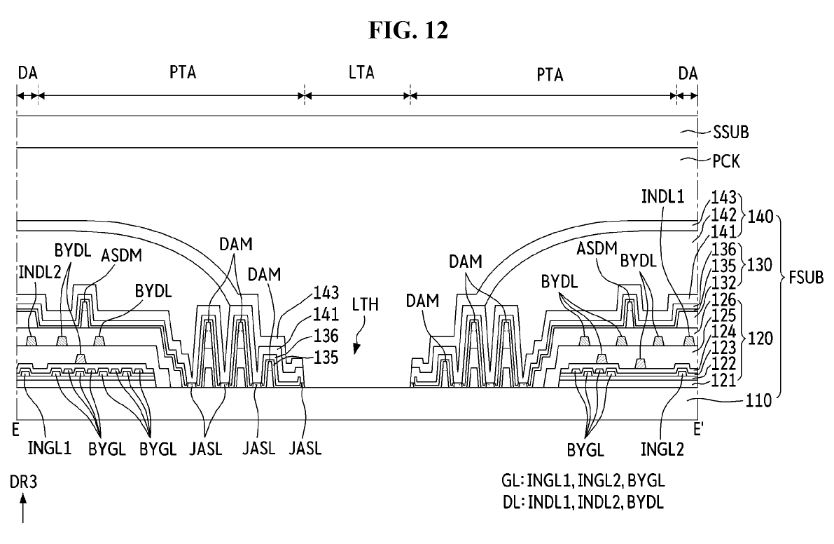

FIG. 12 is a cross-sectional view taken along line E-E' of FIGS. 10 and 11 according to one embodiment.

As shown in FIG. 12, the first substrate FSUB of the display device 100 according to one embodiment may further include at least one light transmitting peripheral dam DAM located between the two or more bonding auxiliary layers JASL.

Each of the at least one light transmitting peripheral dam DAM may include two or more dam layers sequentially stacked.

Each of the two or more dam layers may be in the same layer as one of the first planarization layer 125, the second planarization layer 126, and the pixel defining layer 132.

According to one embodiment, the at least one light transmitting peripheral dam DAM may be located on the support substrate 110.

The first substrate FSUB may further include an auxiliary dam ASDM located on the second planarization layer 126 and overlapping the bypass gate lines BYGL or the bypass data lines BYDL.

When the element layer 130 further includes the auxiliary spacer 132', each of the two or more dam layers may be in the same layer as one of the first planarization layer 125, the second planarization layer 126, the pixel defining layer 132, and the auxiliary spacer 132'.

The second encapsulation layer 142 of the encapsulation layer 140 may be spaced apart from the light transmitting area LTA by the at least one light transmitting peripheral dam DAM.

In other words, the second encapsulation layer 142 including the organic insulating material may not be diffused into the light transmitting area LTA by the at least one light transmitting peripheral dam DAM.

Accordingly, the third encapsulation layer 143 on the second encapsulation layer 142 may be in contact with the first encapsulation layer 141 in a portion of the light transmitting peripheral area PTA between the at least one light transmitting peripheral dam DAM and the light transmitting area LTA.

According to one embodiment, the circuit layer 120 includes the plurality of inorganic layers 121, 122, 123 and 124 and the at least one organic layer 125 and 126.

The plurality of inorganic layers 121, 122, 123 and 124 and the at least one organic layer 125 and 126 may extend to a portion of the light transmitting peripheral area PTA and may be spaced apart from the two or more bonding auxiliary layers JASL.

That is, the plurality of inorganic layers 121, 122, 123 and 124 and the at least one organic layer 125 and 126 may extend to a portion of the light transmitting peripheral area PTA in which the bypass gate lines BYGL and the bypass data lines BYDL are located.

In the process of arranging the second common layer 135 and the second electrode 136 of the element layer 130, the second common layer 135 and the second electrode 136 may be formed in the entire display area DA through a mask corresponding to the display area DA.

Prior to the process of arranging the first encapsulation layer 141, holes overlapping the two or more bonding auxiliary layers JASL and the light transmitting area LTA may be formed in the second common layer 135 and the second electrode 136 by partially removing the second common layer 135 and the second electrode 136.

In one example, the process of partially removing the second common layer 135 and the second electrode 136 may include a laser irradiation process using the two or more bonding auxiliary layers JASL as an etch stop layer.

According to one embodiment, the two or more bonding auxiliary layers JASL may be located on the support substrate 110. In one example, the two or more bonding auxiliary layers JASL may include titanium (Ti).

The first encapsulation layer 141 may be in contact with the two or more bonding auxiliary layers JASL through the holes that overlap the two or more bonding auxiliary layers JASL and are defined in the second common layer 135 and the second electrode 136.

According to one embodiment, the light transmitting hole LTH may be defined in the first encapsulation layer 141 and the third encapsulation layer 143 overlapping the light transmitting area LTA.

According to one embodiment, in order to remove the second common layer 135 and the second electrode 136 overlapping the light transmitting area LTA, one bonding auxiliary layer JASL that is closest to the light transmitting area LTA among the two or more bonding auxiliary layers JASL may extend to the light transmitting area LTA.

In addition, the light transmitting hole LTH may be further defined in the one bonding auxiliary layer JASL that is closest to the light transmitting area LTA among the two or more bonding auxiliary layers JASL.

In other words, in the one bonding auxiliary layer JASL closest to the light transmitting area LTA, a portion overlapping the light transmitting area LTA may serve as a sacrificial layer that is removed due to the formation of the light transmitting hole LTH.

As a result, according to one embodiment, the filling layer PCK filled between the first substrate FSUB and the second substrate SSUB may be in contact with the support substrate 110 of the first substrate FSUB through the light transmitting hole LTH.

Therefore, since only the interface between the first substrate FSUB and the filling layer PCK and the interface between the filling layer PCK and the second substrate SSUB overlap the light transmitting area LTA due to the light transmitting hole LTH overlapping the light transmitting area LTA, the light transmittance of the light transmitting area LTA may be increased. Accordingly, the sensing accuracy of the optical device 18 (see FIG. 2) located below the display device 100 may be improved.

In addition, since the light transmitting hole LTH is not defined in the support substrate 110, leakage of the filling layer PCK due to the light transmitting hole LTH may be prevented, and generation and propagation of cracks in the support substrate 110 due to the light transmitting hole LTH may be reduced. Accordingly, the strength of the display device 100 may be improved, and thus the lifespan and product reliability of the display device 100 may be improved.

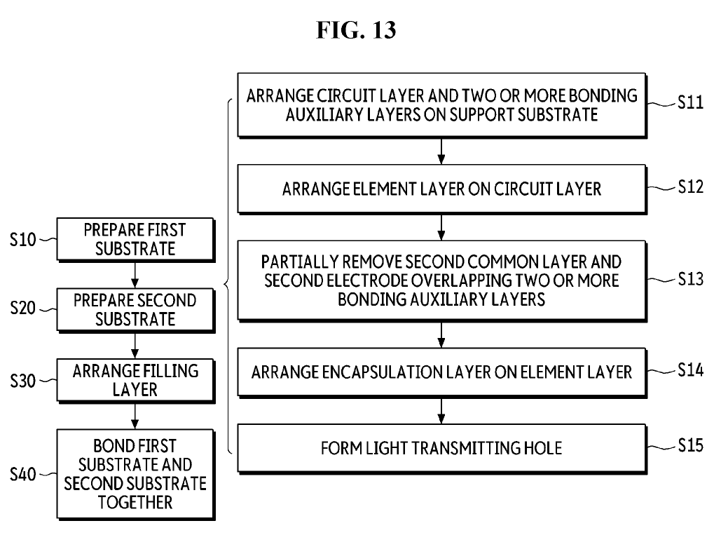

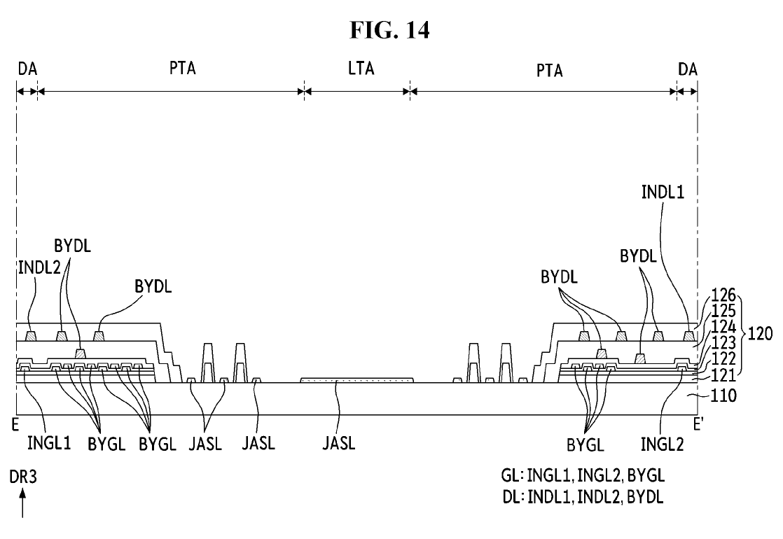

FIG. 13 is a flowchart illustrating a method for fabrication of the display device according to one embodiment. FIGS. 14, 15, 16, 17, and 18 are process diagrams illustrating a step of preparing a first substrate of FIG. 13 according to one embodiment of FIG. 12.

As shown in FIG. 13, a method of manufacturing the display device 100 according to one embodiment may include preparing the first substrate FSUB (step S10), preparing the second substrate SSUB (step S20), arranging the filling layer PCK (step S30), and bonding the first substrate FSUB and the second substrate SSUB together (step S40).

Step S10 of preparing the first substrate FSUB may include arranging the circuit layer 120 and the two or more bonding auxiliary layers JASL on the support substrate 110 (step S11), arranging the element layer 130 on the circuit layer 120 (step S12), partially removing the second common layer 135 and the second electrode 136 overlapping the two or more bonding auxiliary layers JASL (step S13), arranging the encapsulation layer 140 on the element layer 130 (step S14), and forming the light transmitting hole LTH (step S15).

As shown in FIG. 14, in step S11 of arranging the circuit layer 120 and the two or more bonding auxiliary layers JASL, the gate lines GL, the plurality of inorganic layers 121, 122, 123 and 124, the data lines DL, and the at least one organic layer 125 and 126 may be formed.

In addition, in step S11 of arranging the circuit layer 120 and the two or more bonding auxiliary layers JASL, a portion of the dam layers of each of the at least one light transmitting peripheral dam DAM may be formed in the same layer as the at least one organic layer 125 and 126.

The two or more bonding auxiliary layers JASL may be formed together with at least one of the first source/drain conductive layer SDCDL1 (see FIG. 9) on the interlayer-insulating layer 124 or the second source/drain conductive layer SDCDL2 (see FIG. 9) on the first planarization layer 125.

The one bonding auxiliary layer JASL closest to the light transmitting area LTA among the two or more bonding auxiliary layers JASL may overlap not only the periphery of the light transmitting area LTA but also the light transmitting area LTA.

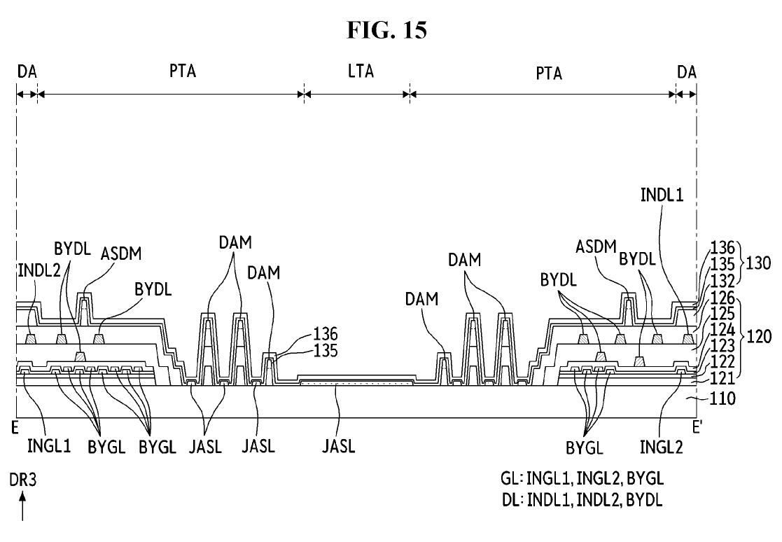

As shown in FIG. 15, in step S12 of arranging the element layer 130 on the circuit layer 120, the second common layer 135 and the second electrode 136 may be entirely formed in the display area DA, and the light transmitting peripheral area PTA and the light transmitting area LTA surrounded by the display area DA.

In addition, in step S12 of arranging the element layer 130 on the circuit layer 120, another portion of the dam layers of each of the at least one light transmitting peripheral dam DAM may be formed in the same layer as the pixel defining layer 132 and the auxiliary spacer 132'.

The second common layer 135 and the second electrode 136 may cover the two or more bonding auxiliary layers JASL and the at least one light transmitting peripheral dam DAM.

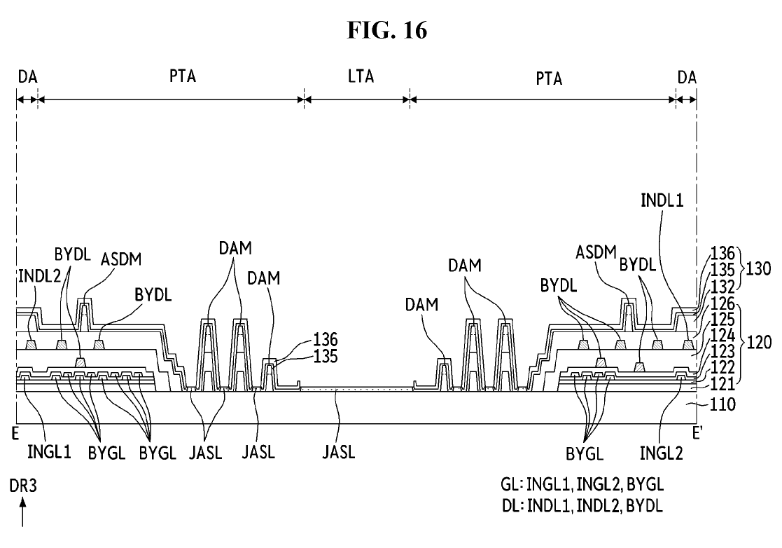

As shown in FIG. 16, in step S13 of partially removing the second common layer 135 and the second electrode 136 overlapping the two or more bonding auxiliary layers JASL, a laser may be irradiated onto portions of the second electrode 136 that overlap the two or more bonding auxiliary layers JASL, so that holes overlapping the two or more bonding auxiliary layers JASL and a hole overlapping the light transmitting area LTA may be formed in the second common layer 135 and the second electrode 136.

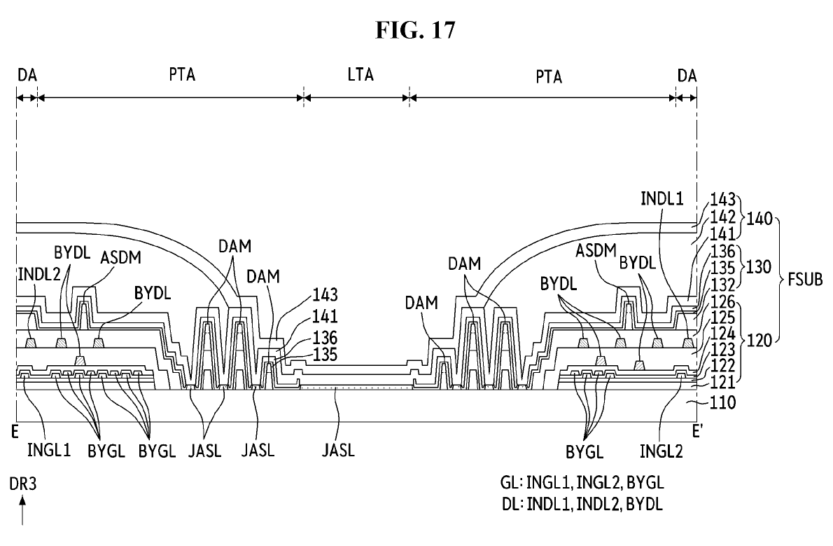

As shown in FIG. 17, in step S14 of arranging the encapsulation layer 140 on the element layer 130, the first encapsulation layer 141 may be formed by stacking an inorganic insulating material on the element layer 130, the second encapsulation layer 142 may be formed through the process of dropping, spreading, and curing an organic insulating material, and the third encapsulation layer 143 may be formed by stacking an inorganic insulating material on the second encapsulation layer 142.

The first encapsulation layer 141 may be in contact with the two or more bonding auxiliary layers JASL through the holes formed in the second common layer 135 and the second electrode 136.

In addition, in a portion of the light transmitting peripheral area PTA between the at least one light transmitting peripheral dam DAM and the light transmitting area LTA, the third encapsulation layer 143 may be in contact with the first encapsulation layer 141.

Thus, inorganic bonding structures by the two or more bonding auxiliary layers JASL, the first encapsulation layer 141, and the third encapsulation layer 143 may be formed in the light transmitting peripheral area PTA. Since sealing can be enhanced by these inorganic bonding structures, permeation of oxygen or moisture due to the light transmitting area LTA may be delayed or prevented.

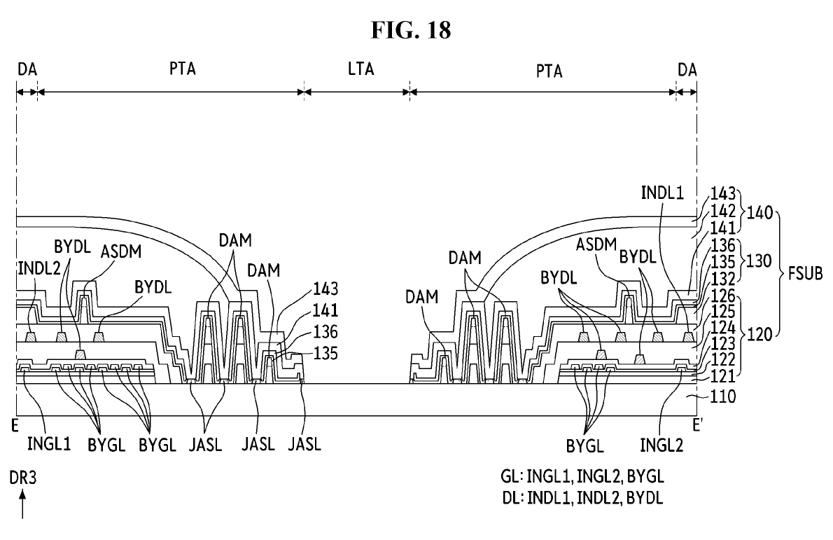

As shown in FIG. 18, in step S15 of forming the light transmitting hole LTH, one bonding auxiliary layer JASL, the first encapsulation layer 141, and the third encapsulation layer 143 may be partially removed to form the light transmitting hole LTH overlapping the light transmitting area LTA.

A portion of the one bonding auxiliary layer JASL overlapping the light transmitting area LTA may be removed by the formation of the light transmitting hole LTH, while the remaining portion thereof may remain in the light transmitting peripheral area PTA in a shape corresponding to the outer boundary of the light transmitting area LTA.

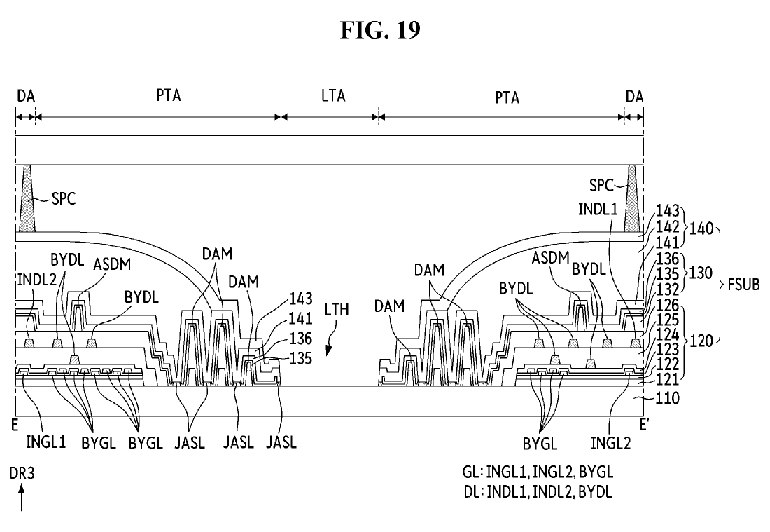

FIGS. 19, 20, 21, 22, 23, 24, 25, 26, and 27 are cross-sectional views taken along line E-E' of FIGS. 10 and 11 according to other embodiments.

The display device 100 of one embodiment shown in FIG. 19 is substantially the same as the display device 100 of one embodiment shown in FIGS. 10, 11, and 12, except that it further includes spacers SPC located between the first substrate FSUB and the second substrate SSUB and arranged in the display area DA, and thus redundant description will be omitted below.

Since a gap between the first substrate FSUB and the second substrate SSUB may be maintained by the spacers SPC, stains or the like caused by variations in the gap between the first substrate FSUB and the second substrate SSUB may be prevented, and thus display quality of the display device 100 may be improved.

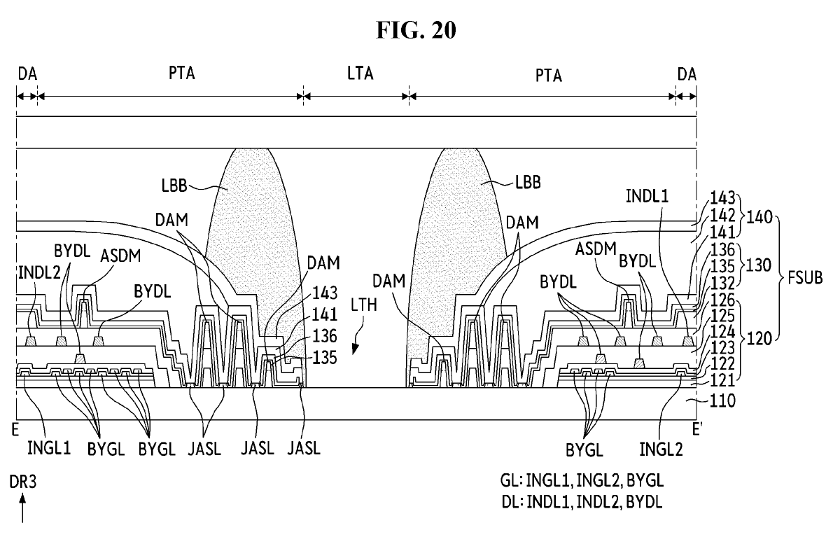

The display device 100 of one embodiment shown in FIG. 20 is substantially the same as the display device 100 of one embodiment shown in FIGS. 10, 11, and 12, except that it further includes a light blocking bank LBB located between the first substrate FSUB and the second substrate SSUB, surrounding the light transmitting area LTA, and overlapping the at least one light transmitting peripheral dam DAM, and thus redundant description will be omitted below.

The light blocking bank LBB may include at least one of a light blocking material that blocks light, a light absorbing material that absorbs light, or a transparent material having a higher refractive index than the filling layer PCK.

According to one embodiment, the light blocking bank LBB may cover the edge of the light transmitting hole LTH. That is, the cross-sections of the third encapsulation layer 143 and the first encapsulation layer 141 corresponding to the edge of the light transmitting hole LTH may be covered by the light blocking bank LBB.

Accordingly, since the cross-sections of the third encapsulation layer 143 and the first encapsulation layer 141 are not exposed to light of the light transmitting area LTA, a light leakage defect in which light from the light transmitting area LTA enters the display area DA through the third encapsulation layer 143 and the first encapsulation layer 141 may be prevented.

As such, according to one embodiment, a light leakage defect in which a light leakage defect in which light from display area DA includes light entered from the light transmitting area LTA enters the display area DA and a light leakage defect in which light from the display area DA enters the light transmitting area LTA may be prevented by the light blocking bank LBB.

Accordingly, degradation in display quality due to light leakage defects may be prevented, and a reduction in sensing accuracy of the optical device 18 may be prevented.

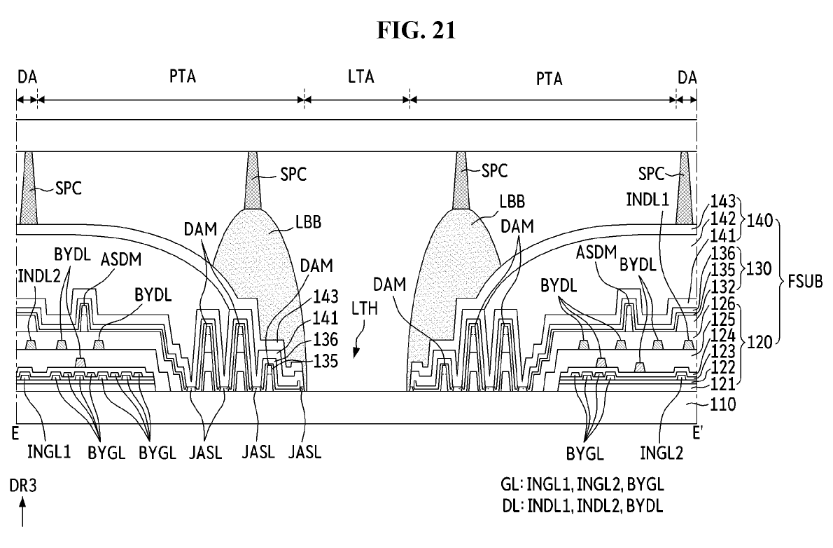

The display device 100 of one embodiment shown in FIG. 21 is substantially the same as the display device 100 of one embodiment shown in FIG. 20, except that it further includes spacers SPC and some of the spacers SPC are located on the light blocking bank LBB, and thus redundant description will be omitted below.

Since the spacers SPC are substantially the same as those of one embodiment shown in FIG. 19, redundant description will be omitted below.

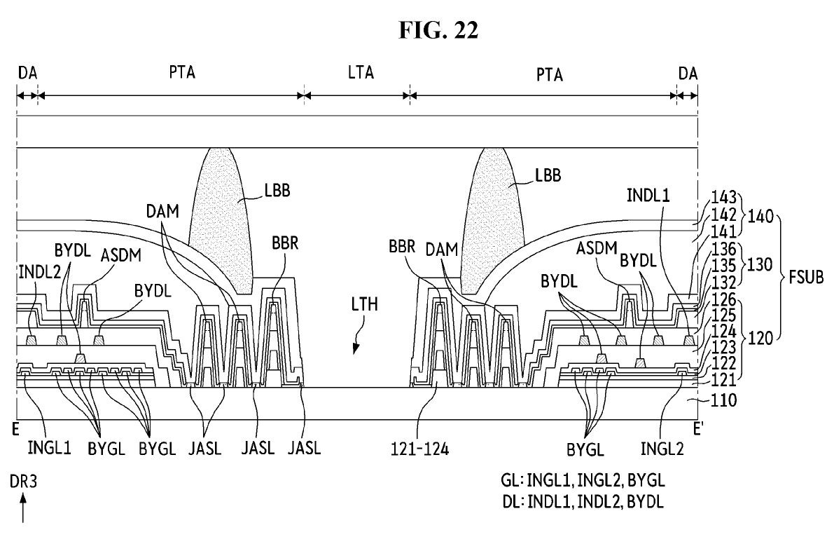

The display device 100 of one embodiment shown in FIG. 22 is substantially the same as the display device 100 of one embodiment shown in FIG. 20, except that the first substrate FSUB further includes a bank barrier BBR, which is located between the at least one light transmitting peripheral dam DAM and the light transmitting area LTA and surrounds the light transmitting area LTA in a plan view, and thus redundant description will be omitted below.

The bank barrier BBR may be located on the plurality of inorganic layers 121, 122, 123 and 124.

Accordingly, the height of the peak of the bank barrier BBR with respect to the support substrate 110 may be greater than the height of the peak of the at least one light transmitting peripheral dam DAM with respect to the support substrate 110.

Therefore, the light blocking bank LBB may be spaced apart from the light transmitting area LTA by the bank barrier BBR.

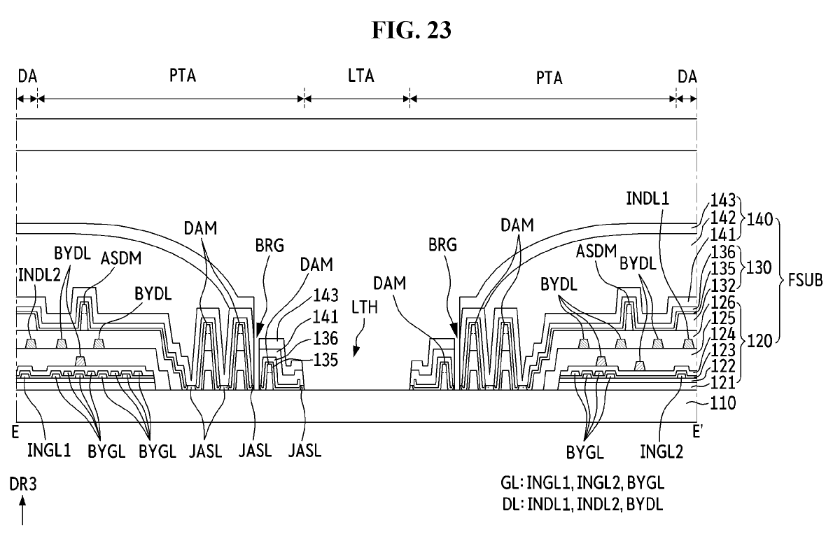

The display device 100 of one embodiment shown in FIG. 23 is substantially the same as the display device 100 of one embodiment shown in FIGS. 10, 11, and 12, and 12, except that the first substrate FSUB further defines therein at least one separation groove BRG, which is located in a portion of the light transmitting peripheral area PTA between the at least one light transmitting peripheral dam DAM and the light transmitting area LTA, surrounds the light transmitting area LTA, and is defined in the third encapsulation layer 143 and the first encapsulation layer 141, and thus redundant description will be omitted below.

Since the third encapsulation layer 143 and the first encapsulation layer 141 are separated by the at least one separation groove BRG, a light leakage defect in which light from the light transmitting area LTA enters the display area DA through the third encapsulation layer 143 and the first encapsulation layer 141 may be prevented.

Accordingly, degradation in display quality due to the light transmitting area LTA may be prevented.

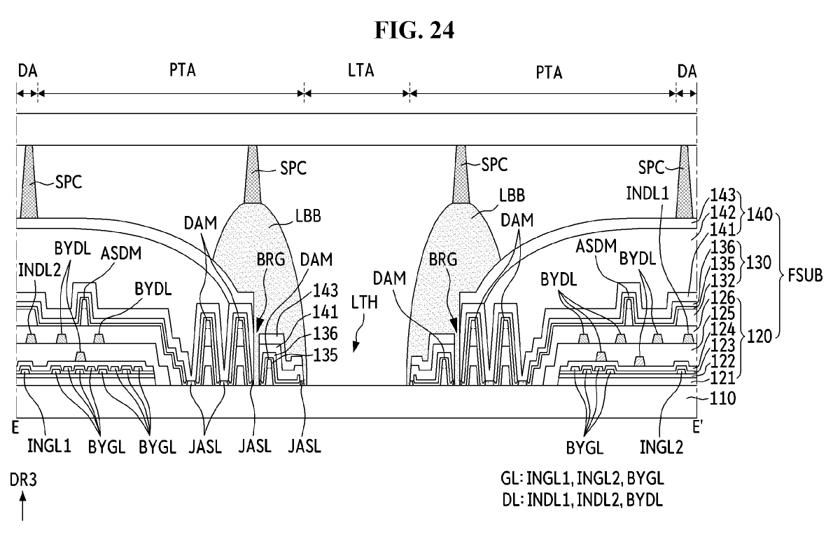

The display device 100 of one embodiment shown in FIG. 24 is substantially the same as the display device 100 of one embodiment shown in FIG. 21, except that the first substrate FSUB further defines therein at least one separation groove BRG, and thus redundant description will be omitted below.

Since the at least one separation groove BRG is substantially the same as a groove of one embodiment shown in FIG. 23, redundant description will be omitted below.

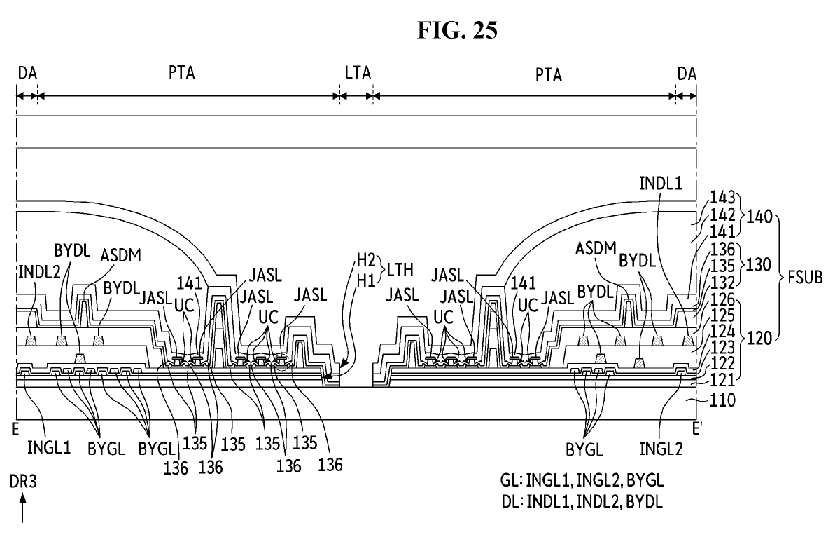

The display device 100 of one embodiment shown in FIG. 25 is substantially the same as the display device 100 of one embodiment shown in FIGS. 10, 11, and 12, except that each of the two or more bonding auxiliary layers JASL of the first substrate FSUB includes an undercut structure UC, and the light transmitting hole LTH includes a first hole H1 and a second hole H2, and thus redundant description will be omitted below.

According to one embodiment, the plurality of inorganic layers 121, 122, 123 and 124 of the circuit layer 120 may extend to the light transmitting peripheral area PTA.

The at least one organic layer 125 and 126 may extend to a portion of the light transmitting peripheral area PTA in which the bypass data lines BYDL are located.

The two or more bonding auxiliary layers JASL and the at least one light transmitting peripheral dam DAM may be located on the plurality of inorganic layers 121, 122, 123 and 124.

Each of the two or more bonding auxiliary layers JASL may include the undercut structure UC formed by a main layer ML and a roof layer RL that is located on the main layer ML and protrudes beyond the main layer ML.

Due to the undercut structure UC of each of the two or more bonding auxiliary layers JASL, the second common layer 135 and the second electrode 136 may not entirely cover the side surface of the main layer ML in each of the two or more bonding auxiliary layers JASL, and may be partially located only on a lower portion of the side surface of the main layer ML where the influence of the roof layer RL is relatively small.

As a result, the first encapsulation layer 141 may be in contact with a portion (i.e., an upper portion) of the side surface of the main layer ML adjacent to the roof layer RL in each of the two or more bonding auxiliary layers JASL.

Accordingly, inorganic bonding structures between the first encapsulation layer 141 and the two or more bonding auxiliary layers JASL may be disposed in the light transmitting peripheral area PTA.

According to one embodiment, the light transmitting hole LTH may include the first hole H1 defined in the plurality of inorganic layers 121, 122, 123 and 124, and the second hole H2 defined in the second common layer 135, the second electrode 136, the first encapsulation layer 141, and the third encapsulation layer 143.

According to one embodiment, the width of the second hole H2 may be smaller than the width of the first hole H1. That is, the second common layer 135, the second electrode 136, the first encapsulation layer 141, and the third encapsulation layer 143 may cover the cross-sections of the plurality of inorganic layers 121, 122, 123 and 124 at the edge of the first hole H1.

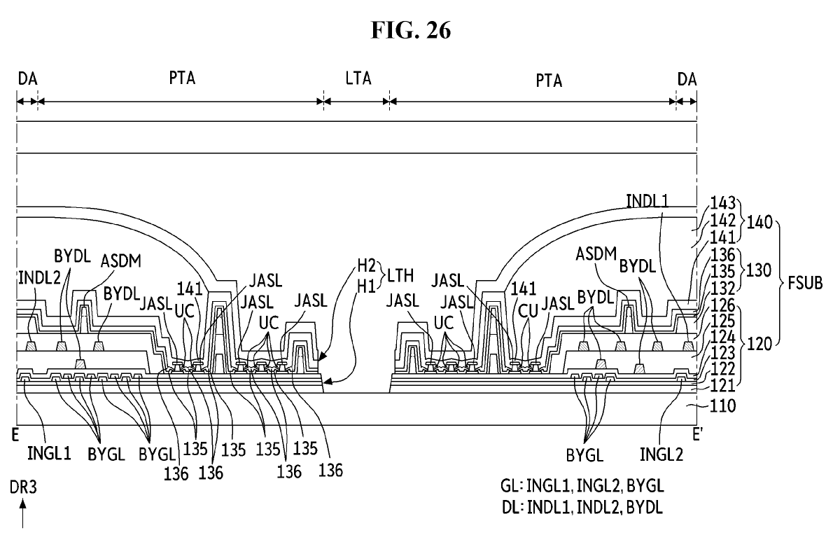

The display device 100 of one embodiment shown in FIG. 26 is substantially the same as the display device 100 of one embodiment shown in FIG. 25, except that the second hole H2 is formed to have a greater width than the first hole H1, and thus redundant description will be omitted below.

According to one embodiment, the second common layer 135, the second electrode 136, the first encapsulation layer 141, and the third encapsulation layer 143 may be located on the plurality of inorganic layers 121, 122, 123 and 124.

That is, the cross-sections of the plurality of inorganic layers 121, 122, 123 and 124 at the edge of the first hole H1 and the cross-sections of the second common layer 135, the second electrode 136, the first encapsulation layer 141, and the third encapsulation layer 143 at the edge of the second hole H2 may be covered only by the filling layer PCK.

In this manner, the number of interfaces at the edge of the light transmitting area LTA may be reduced, thereby improving the light transmittance of the light transmitting area LTA.

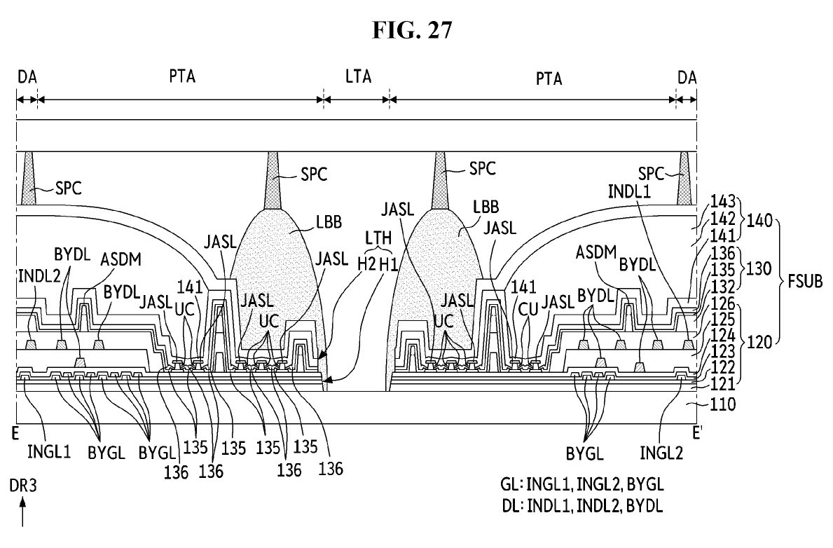

The display device 100 of one embodiment shown in FIG. 27 is substantially the same as the display device 100 of one embodiment shown in FIG. 25, except that it further includes a light blocking bank LBB and spacers SPC, and thus redundant description will be omitted below.

The light blocking bank LBB is substantially the same as the light blocking bank of one embodiment shown in FIG. 20, and thus redundant description will be omitted below.

The spacers SPC are substantially the same as those of one embodiment shown in FIG. 19, and thus redundant description will also be omitted below.

The display device 100 of each embodiment as described above may be applied to various electronic devices 10.

The electronic device 10 according to one embodiment may include the display device 100 described above.

Additionally, the electronic device 10 according to one embodiment may further include a module or device having other additional functions in addition to the display device 100.

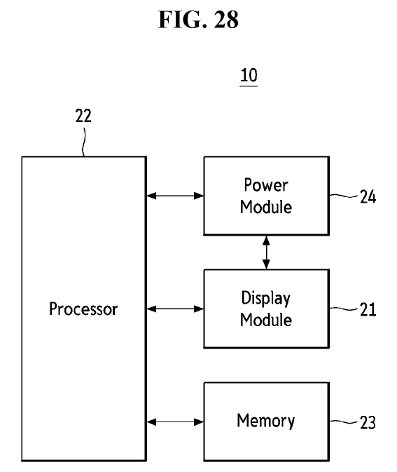

FIG. 28 is a block diagram of an electronic device according to one embodiment.

Referring to FIG. 28, an electronic device 10 according to one embodiment may include a display module 21, a processor 22, a memory 23, and a power module 24.

The display module 21 may include the display device 100 that displays an image.

The processor 22 may include at least one of a central processing unit (CPU), an application processor (AP), a graphic processing unit (GPU), a communication processor (CP), an image signal processor (ISP), or a controller.

The memory 23 may store data information required for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device 100 may include the display module 21, and the processor 22, the memory 23, and the power module 24 may be provided in the form of other devices in the electronic device 10 other than the display device 100.

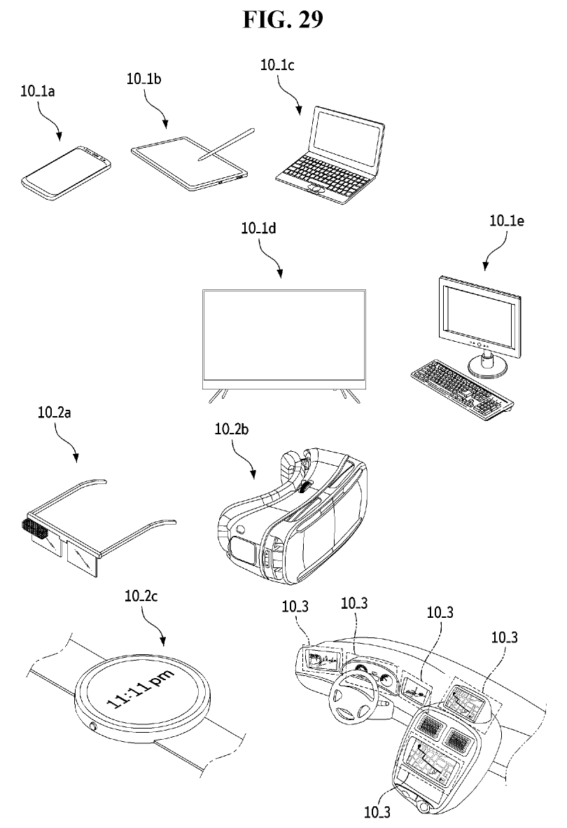

FIG. 29 is schematic views of electronic devices according to various embodiments.

Referring to FIG. 29, the electronic devices 10 according to the embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a first substrate and a second substrate facing each other and bonded together; and
a filling layer filled between the first substrate and the second substrate,
wherein each of the first substrate and the second substrate comprises:
a display area in which emission areas are arranged;
a non-display area located around the display area in a plan view;
a light transmitting area surrounded by the display area in the plan view; and
a light transmitting peripheral area located between the light transmitting area and the display area in the plan view, and
wherein the first substrate comprises:
a support substrate;
two or more bonding auxiliary layers located in the light transmitting peripheral area, having a ring shape surrounding the light transmitting area, and spaced apart from each other in the plan view;
a circuit layer located on the support substrate;
an element layer located on the circuit layer; and
an encapsulation layer covering the element layer,
wherein the first substrate defines therein a light transmitting hole overlapping the light transmitting area,
wherein the encapsulation layer comprises:
a first encapsulation layer located on the element layer and the two or more bonding auxiliary layers and containing an inorganic insulating material;
a second encapsulation layer located on the first encapsulation layer and containing an organic insulating material; and
a third encapsulation layer covering the second encapsulation layer and containing an inorganic insulating material,
wherein the light transmitting hole is defined in the first encapsulation layer and the third encapsulation layer, and
the filling layer is in contact with the support substrate through the light transmitting hole.

2. The display device of claim 1, wherein the first substrate further comprises at least one light transmitting peripheral dam located between the two or more bonding auxiliary layers,
the second encapsulation layer is spaced apart from the light transmitting area by the at least one light transmitting peripheral dam, and
in a portion of the light transmitting peripheral area between the at least one light transmitting peripheral dam and the light transmitting area, the third encapsulation layer is in contact with the first encapsulation layer.

3. The display device of claim 2, wherein the element layer comprises:
first electrodes located in the emission areas;
a pixel defining layer located in a non-emission area between the emission areas of the display area and covering edges of the first electrodes;
first common layers located on the first electrodes;
light emitting layers located on the first common layers;
a second common layer located on the pixel defining layer and the light emitting layers; and
a second electrode located on the second common layer,
wherein the second common layer and the second electrode overlap the display area, the light transmitting peripheral area, and the light transmitting area, and
the first encapsulation layer is in contact with the two or more bonding auxiliary layers through holes which overlap the two or more bonding auxiliary layers in the plan view, respectively, and are defined in the second common layer and the second electrode.

4. The display device of claim 3, wherein the two or more bonding auxiliary layers are located on the support substrate, and
the light transmitting hole is further defined in one bonding auxiliary layer, which is closest to the light transmitting area among the two or more bonding auxiliary layers.

5. The display device of claim 3, further comprising a light blocking bank located between the first substrate and the second substrate, surrounding the light transmitting area, and overlapping the at least one light transmitting peripheral dam in the plan view,
wherein the light blocking bank contains at least one of a light blocking material that blocks light, a light absorbing material that absorbs light, or a transparent material that has a higher refractive index than the filling layer.

6. The display device of claim 5, further comprising spacers located between the first substrate and the second substrate, overlapping the non-emission area and the light transmitting peripheral area, and spaced apart from each other,
wherein some of the spacers are located between the light blocking bank and the second substrate.

7. The display device of claim 5, wherein the first substrate further comprises a bank barrier located between the at least one light transmitting peripheral dam and the light transmitting area and surrounding the light transmitting area in the plan view.

8. The display device of claim 7, wherein the circuit layer comprises:
a plurality of inorganic layers stacked on the support substrate and each containing an inorganic insulating material; and
at least one organic layer located on the plurality of inorganic layers and containing an organic insulating material,
wherein the at least one light transmitting peripheral dam is located on the support substrate and spaced apart from the plurality of inorganic layers and the at least one organic layer in the plan view, and
the bank barrier is located on the plurality of inorganic layers.

9. The display device of claim 3, wherein the at least one light transmitting peripheral dam includes a plurality of light transmitting peripheral dam, and the first substrate further defines therein at least one separation groove, which is located in a portion of the light transmitting peripheral area between the plurality of light transmitting peripheral dams, surrounds the light transmitting area in the plan view, and is defined in the third encapsulation layer and the first encapsulation layer.

10. The display device of claim 2, wherein the element layer comprises:
first electrodes located in the emission areas;
a pixel defining layer located in a non-emission area between the emission areas of the display area and covering edges of the first electrodes;
first common layers located on the first electrodes;
light emitting layers located on the first common layers;
a second common layer located on the pixel defining layer and the light emitting layers; and
a second electrode located on the second common layer,
wherein the second common layer and the second electrode overlap the display area, the light transmitting peripheral area, and the light transmitting area,
each of the two or more bonding auxiliary layers has an undercut structure formed by a main layer and a roof layer located on the main layer and protruding beyond the main layer, and
the first encapsulation layer is in contact with a portion of a side surface of the main layer adjacent to the roof layer in each of the two or more bonding auxiliary layers.

11. The display device of claim 10, wherein the circuit layer comprises:
a plurality of inorganic layers located on the support substrate, each containing an inorganic insulating material, and sequentially stacked; and
at least one organic layer located on the plurality of inorganic layers and containing an organic insulating material,
wherein the two or more bonding auxiliary layers and the at least one light transmitting peripheral dam are spaced apart from the at least one organic layer and are arranged on the plurality of inorganic layers, and
the light transmitting hole comprises:
a first hole defined in the plurality of inorganic layers; and
a second hole defined in the second common layer, the second electrode, the first encapsulation layer, and the third encapsulation layer.

12. The display device of claim 11, wherein the second hole has a greater width than the first hole, and
at a periphery of the light transmitting hole, the second common layer, the second electrode, the first encapsulation layer, and the third encapsulation layer are located on the plurality of inorganic layers.

13. The display device of claim 12, further comprising a light blocking bank located between the first substrate and the second substrate, surrounding the light transmitting area, and overlapping the at least one light transmitting peripheral dam in the plan view,
wherein the light blocking bank contains at least one of a light blocking material that blocks light, a light absorbing material that absorbs light, or a transparent material that has a higher refractive index than the filling layer, and covers an edge of the light transmitting hole.

14. An electronic device comprising:
a display device, which displays an image;
a memory, which stores an application;
a processor, which executes the application and transmits an image data signal and an input control signal to the display device; and
a power module, which transmits power to the display device,
wherein the display device comprises:
a first substrate and a second substrate facing each other and bonded together; and
a filling layer filled between the first substrate and the second substrate,
wherein each of the first substrate and the second substrate comprises:
a display area in which emission areas are arranged;
a non-display area located around the display area in a plan view;
a light transmitting area surrounded by the display area in the plan view; and
a light transmitting peripheral area located between the light transmitting area and the display area in the plan view,
wherein the first substrate comprises:
a support substrate;
two or more bonding auxiliary layers located in the light transmitting peripheral area, having a ring shape surrounding the light transmitting area, and spaced apart from each other in the plan view;
at least one light transmitting peripheral dam located between the two or more bonding auxiliary layers;
a circuit layer located on the support substrate;
an element layer located on the circuit layer; and
an encapsulation layer covering the element layer,
wherein the first substrate defines therein a light transmitting hole overlapping the light transmitting area,
wherein the encapsulation layer comprises:
a first encapsulation layer located on the element layer and the two or more bonding auxiliary layers and containing an inorganic insulating material;
a second encapsulation layer located on the first encapsulation layer and containing an organic insulating material; and
a third encapsulation layer covering the second encapsulation layer and containing an inorganic insulating material,
wherein the light transmitting hole is defined in the first encapsulation layer and the third encapsulation layer,
the filling layer is in contact with the support substrate through the light transmitting hole,
the second encapsulation layer is spaced apart from the light transmitting area by the at least one light transmitting peripheral dam, and
in a portion of the light transmitting peripheral area between the at least one light transmitting peripheral dam and the light transmitting area, the third encapsulation layer is in contact with the first encapsulation layer.

15. The electronic device of claim 14, wherein the display device further comprises a light blocking bank located between the first substrate and the second substrate, surrounding the light transmitting area, and overlapping the at least one light transmitting peripheral dam in the plan view, and
the light blocking bank contains at least one of a light blocking material that blocks light, a light absorbing material that absorbs light, or a transparent material that has a higher refractive index than the filling layer.

16. The electronic device of claim 15, wherein the first substrate further comprises a bank barrier located between the at least one light transmitting peripheral dam and the light transmitting area and surrounding the light transmitting area in the plan view.

17. The electronic device of claim 14, wherein the at least one light transmitting peripheral dam includes a plurality of light transmitting peripheral dam, and the display device further defines therein at least one separation groove, which is located in a portion of the light transmitting peripheral area between the plurality of light transmitting peripheral dams, surrounds the light transmitting area in the plan view, and is defined in the third encapsulation layer and the first encapsulation layer.

18. The electronic device of claim 17, wherein the display device further comprises a light blocking bank located between the first substrate and the second substrate, surrounding the light transmitting area, and overlapping the at least one light transmitting peripheral dam in the plan view,
the light blocking bank contains at least one of a light blocking material that blocks light, a light absorbing material that absorbs light, or a transparent material that has a higher refractive index than the filling layer, and
the light blocking bank covers the at least one separation groove.

19. The electronic device of claim 14, wherein the element layer comprises:
first electrodes located in the emission areas;
a pixel defining layer located in a non-emission area between the emission areas of the display area and covering edges of the first electrodes;
first common layers located on the first electrodes;
light emitting layers located on the first common layers;
a second common layer located on the pixel defining layer and the light emitting layers; and
a second electrode located on the second common layer,
wherein the second common layer and the second electrode overlap the display area, the light transmitting peripheral area, and the light transmitting area, and
the first encapsulation layer is in contact with the two or more bonding auxiliary layers through holes which overlap the two or more bonding auxiliary layers in the plan view, respectively, and are defined in the second common layer and the second electrode.

20. The electronic device of claim 14, wherein the element layer comprises:
first electrodes located in the emission areas;
a pixel defining layer located in a non-emission area between the emission areas of the display area and covering edges of the first electrodes;
first common layers located on the first electrodes;
light emitting layers located on the first common layers;
a second common layer located on the pixel defining layer and the light emitting layers; and
a second electrode located on the second common layer,
wherein the second common layer and the second electrode overlap the display area, the light transmitting peripheral area, and the light transmitting area,
each of the two or more bonding auxiliary layers has an undercut structure formed by a main layer and a roof layer located on the main layer and protruding beyond the main layer,
the first encapsulation layer is in contact with a portion of a side surface of the main layer adjacent to the roof layer in each of the two or more bonding auxiliary layers, and
the circuit layer comprises:
a plurality of inorganic layers located on the support substrate, each containing an inorganic insulating material, and sequentially stacked; and
at least one organic layer located on the plurality of inorganic layers and containing an organic insulating material,
wherein the two or more bonding auxiliary layers and the at least one light transmitting peripheral dam are spaced apart from the at least one organic layer and are located on the plurality of inorganic layers, and
the light transmitting hole comprises:
a first hole defined in the plurality of inorganic layers; and
a second hole defined in the second common layer, the second electrode, the first encapsulation layer, and the third encapsulation layer.
